(19) United States
(12) Patent Application Publication
(10) Pub. No.: US 2013/0117632 A1
(43) Pub. Date: May 9, 2013

(54) STORAGE CONTROL APPARATUS

(71) Applicant: Sony Corporation, Tokyo (JP)

(72) Inventors: Yasushi Fujinami, Tokyo (JP); Keiichi Tsutsui, Kanagawa (JP); Kenichi Nakanishi, Tokyo (JP); Naohiro Adachi, Kanagawa (JP); Hideaki Okubo, Saitama (JP); Makiko Yamamoto, Tokyo (JP)

(73) Assignee: SONY CORPORATION, Tokyo (JP)

(21) Appl. No.: 13/666,738

(22) Filed: Nov. 1, 2012

(30) Foreign Application Priority Data
Nov. 8, 2011 (JP) 2011-244266
Jan. 13, 2012 (JP) 2012-004578

(51) Int. Cl. H03M 13/05

(52) U.S. Cl. 714/763; 714/E11.034

(57) ABSTRACT

Embodiments of the technology disclosed herein are intended to flexibly set the rules of attaching error correction codes to a group of data sequences stored in a memory. A storage control apparatus has an error correction code attachment rule hold block and an error correction portion. The error correction code attachment rule hold block holds the rules of attaching error correction codes to a group of data sequences stored in a memory by relating the rules with the data for each address of the group of data sequences. If an access occurs to the memory, the error correction portion executes error correction processing on a group of data sequences stored in the memory in accordance with the attachment rules related to the address at which the access occurred.

### BACKGROUND

The technology disclosed herein relates to a storage control apparatus. To be more specific, the technology disclosed herein relates to a storage control apparatus, a storage apparatus, and an information processing system which execute an error correction on the basis of an error correction code, and methods for these apparatuses and system, and a program that makes a computer execute these methods.

In use of a memory, an ECC (Error Correction Code) may be attached in order to detect an error in the data stored in the memory and correct the detected error. Especially, with nonvolatile memories, it is a general practice to use this error correction code. To be more specific, at the time of writing data to a memory, an error correction code is generated to be written to the memory along with the data and, at the time of reading the data, the error correction code is read at the same time to execute error correction processing, thereby improving memory data retention characteristics.

When the above-mentioned error correction code is used, it is sometimes desired to change the degree of data retention characteristics for each memory area. For example, a semiconductor storage apparatus was proposed in which, by assuming that the error occurrence ratio be higher in odd-numbered page than even-numbered page, more parity bits are allocated to the odd-numbered page of the continuous two odd-numbered and even numbered pages (refer to Japanese Patent Laid-open No. 2009-282923, for example).

Because data retention characteristics deteriorate as the number of rewrites increases, the attachment of stronger error correction codes leads to enhanced reliability. However, this increases parity size, making it necessary to enlarge the capacity of redundant areas; for example, in the case of a small data unit such as 32 bytes for example, the problem of increased storage cost arises. On the other hand, in the case of a large data unit such as 512 bytes for example, the capacity occupied by the parity bits can be restrained relatively small, thereby improving the problem of the increased storage cost. Therefore, in balancing performance and capacity efficiency, it is important to store data by selecting optimum one of the data sizes of 32 bytes and 512 bytes in accordance with the contents of the data to be stored and the state of a memory cell in which this data is stored. For example, a semiconductor memory system was proposed in which one of the first ECC and the second ECC is used by arranging ECC specification information for the data of each page of the memory (refer to Japanese Patent Laid-open No. 2008-192054, for example).

### SUMMARY

In the related-art technologies mentioned above, error correction codes of different schemes are attached between memory pages. It should be noted however that, in the related-art technologies mentioned above, more parity bits are allocated to one of odd-numbered page and even-numbered page in accordance with the magnitude of error occurrence ratio, so that the allocation of the number of bits is automatically determined by error occurrence ratio. On the other hand, it is sometimes desired, in a file system for example, to enhance data retention characteristics of a particular file. In this case, it is necessary to set a scheme of error correction code as desired from the system side.

In the related-art technology disclosed in Japanese Patent Laid-open No. 2008-192054, one of two different error correction codes is selected by specifying an error correction code type on the basis ECC specification information. In this case, the configuration of data on a write basis to be written to a nonvolatile memory is made up of a data section in which data is stored and a redundant section in which an error correction code and so on are stored. In this case, if the data in the data section and the error correction code in the redundant section are related with each other on a one-to-one basis, then an error correction code can be generated every time data is written in one write unit. However, if the size in which an error correction code is generated is relatively large, the data included in one write unit alone cannot generate an error correction code, thereby making it necessary to collectively generate error correction codes for the data extending over two or more write units. Consequently, in write processing, a write unit is generated after the generation of error correction codes. In the case of read processing, error correction processing is executed after the data extending over two or more read units and error correction codes are bundled.

Therefore, the present disclosure addresses the above-identified and other problems associated with related-art methods and apparatuses and solves the addressed problems by flexibly setting the rules of attaching error correction codes to a group of data sequences in a memory.

In carrying out the technology disclosed herein and according to a first mode thereof, there is provided a storage control apparatus or a storage control method for this storage control apparatus. The storage control apparatus has an error correction code attachment rule hold block configured to hold attachment rules of attaching error correction codes to a group of data sequences stored in memory by relating the attachment rules to the group of data sequences for each address of the group of data sequences; and an error correction portion configured, if an access occurs to the memory, to execute error correction on the group of data sequences stored in the memory in accordance with the attachment rules related with an access address at which the access occurred. This novel setup allows error correction on the basis of the error correction code attachment rules defined beforehand for a group of data sequences.

In the above-mentioned first mode, these attachment rules may define one of the cases in which the error correction codes are generated from a whole of the group of data sequences and the error correction codes are generated independently of each of a plurality of partial data sequences configuring the group of data sequences. This novel setup allows error correction on the basis of the defined error correction code attachment rules for the group of all data sequences or partial data sequences.

In the above-mentioned first mode, if the attachment rules related with the access address are found defining that the error correction codes are generated independently of each of a plurality of partial data sequences configuring the group of data sequences, the error correction portion may execute error correction only on a partial data sequence related with the access among the plurality of partial data sequences. This novel setup allows skipping of error correction to be executed on the partial data sequences other than those associated with access.

In the above-mentioned first mode, the storage control apparatus may further has an error correction code generation portion configured, if a write access to the memory occurs, to generate an error correction code for write data associated with the write access in accordance with the attachment rules specified in the write access. This novel setup allows the generation of the above-mentioned error correction code for write data with the write access as a trigger. In addition, in the above-mentioned storage control apparatus, if the attachment rules related with the write address are found defining that the error correction code is generated independently of each of a plurality of partial data sequences configuring the group of data sequences, the error correction code generation portion may generate an error correction code only for a partial data sequence associated with the write access among the plurality of partial data sequences. This novel setup allows skipping of the generation of error correction codes for the partial data sequences other than the partial data sequence associated with write access.

In the above-mentioned first mode, the error correction code attachment rule hold block may hold the attachment rules as instructed by a host computer that issues a request. This novel setup allows the holding of the attachment rules with an instruction by the host computer used as a trigger.

In the above-mentioned first mode, if a write access to the memory occurs, the error correction code attachment rule hold block may hold the attachment rules specified in the write access by relating the attachment rules with a write address associated with the write access. This novel setup allows holding of the attachment rules with a write access used as a trigger.

In the above-mentioned first mode, the storage control apparatus further has an address translation block configured, if an access address to the memory is a logical address, to translate the logical address to a physical address and output the physical address to the memory. In this configuration, the error correction code attachment rule hold block may hold the attachment rules by relating the attachment rules with the logical address of each of the group of data sequences, and the error correction portion may execute error correction on the group of data sequences stored in the memory in accordance with the attachment rules related with the logical address. This novel setup allows the definition of the error correction code attachment rules for each logical address of a group of data sequences.

In the above-mentioned first mode, the storage control apparatus still further has an address translation block configured, if an access address to the memory is a logical address, to translate the logical address to a physical address and output the physical address to the memory. In this configuration, the error correction code attachment rule hold block may hold the attachment rules by relating the physical address of each of the group of data sequences, and the error correction portion may execute error correction on the plurality of data sequences stored in the memory in accordance with the attachment rules related with the physical address. This novel setup allows the definition of the error correction code attachment rules for each physical address of a group of data sequences.

In carrying out the technology disclosed herein and according a second mode thereof, there is provided a storage apparatus. The storage apparatus has a memory configured to store a group of data sequences along with error correction codes for this group of data sequences in a data area; an error correction code attachment rule hold block configured to hold error correction code attachment rules for the above-mentioned group of data sequences by relating the these rules with each address of the above-mentioned data sequence; and an error correction portion configured, if an access to the above-mentioned memory occurs, to execute error correction on the above-mentioned group of data sequences stored in the memory by following the above-mentioned attachment rules related with each access address. This novel setup allows the execution of error correction on the basis of the error correction code attachment rules defined beforehand for the group of data sequences stored in the memory.

In the above-mentioned second mode, the attachment rules may define whether the above-mentioned error correction codes are generated from the whole of the above-mentioned group of data sequences or these codes are generated independently of each of two or more partial data sequences making up the above-mentioned group of data sequences. If the attachment rules define that the error correction codes are generated independently of each of the two or more partial data sequences making up the above-mentioned group of data sequences, then the memory may store the error correction codes at locations continuous to each of the two or more partial data sequences. This novel setup facilitates the storing of the partial data sequences and the error correction codes at continuous locations to collectively read these partial data sequences and error correction codes.

It should be noted that, in the above-mentioned second mode, the above-mentioned memory is a nonvolatile memory.

In carrying out the technology disclosed herein and according to a third mode thereof, there is provided an information processing system. The information processing system has a memory configured to store a group of data sequences along with error correction codes for this group of data sequences; an error correction code attachment rule hold block configured to hold error correction code attachment rules for the above-mentioned group of data sequences by relating the these rules with each address of the above-mentioned data sequence; an error correction portion configured, if an access to the above-mentioned memory occurs, to execute error correction on the above-mentioned group of data sequences stored in the memory by following the above-mentioned attachment rules related with each access address; and a host computer that issues a request to the above-mentioned memory for read or writing the above-mentioned data area. This novel setup allows, when a memory access request from the host computer is processed, the execution of error correction by following the error correction codes attachment rules defined beforehand for a group of data sequences stored in the memory.

The technology disclosed herein is indented to solve the above-mentioned problems. In carrying out the above-mentioned technology and according to a fourth mode thereof, there is provided a storage control apparatus. The storage control apparatus has a first write unit generation portion configured, if a write command of a first mode is issued to a memory, to generate, as a first write unit, write data by pairing data obtained by delimiting, by a first size smaller than an access unit of the memory, write data associated with the write command of the first mode with a first error correction code for the data and attaching mode information indicative of the first mode to each pair. The storage control apparatus further has a second write unit generation portion configured, if a write command of a second mode is issued to the memory, to generate, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair. The storage control apparatus further has a write processing portion configured, if the write command of the first mode is issued to same memory, to write the first write unit to the memory as an access unit and, if the write command of the second mode is issued to the memory, to write the second write unit to the memory as the access unit. This novel setup allows the writing of data to the memory without waiting for the generation of error correction codes in any one of the first mode and the second mode.

In the above-mentioned fourth mode, the storage control apparatus may further has a read processing portion configured to read the access unit from the memory to extract the mode information. The storage control apparatus further has a first error correction processing portion configured, if the mode information is indicative of the first mode, to execute error correction on the basis of the data of the first size included in the access unit and the first error correction code. The storage control apparatus further has a second error correction processing portion configured, if the mode information is indicative of the second mode, to execute error correction on the basis of the data delimited by the predetermined size included in the access unit and the second error correction code. This novel setup allows the execution of error correction without separately holding the data of halfway in the processing in any one of the first mode and the second mode.

In the above-mentioned fourth mode, the storage control apparatus may further has a first error correction code generation portion configured to generate a first error correction code for the data of the first size; and a second error correction code generation portion configured to generate a second error correction code for the data of the second size. This novel setup allows the generation of error correction codes having the size matching the mode information.

In the above-mentioned fourth mode, the mode information may be stored at a predetermined location of the access unit. The novel setup allows the determination of the first mode or the second mode by referencing a predetermined location in an access unit. In this case, the mode information may be especially stored at the beginning of in the access unit. This novel setup allows the determination of the first mode or the second mode by referencing the beginning of each access unit.

In the above-mentioned fourth mode, the first write unit generation portion and the second write unit generation portion may attach a third error correction code of the mode information to the mode information. This novel setup allows the independence of the mode information from other data in handling. Especially, in this case, the above-mentioned third error correction code may be an error correction code for executing error correction by a bit majority rule. In addition, in this case, the above-mentioned read processing portion may execute error correction on the mode information on the basis of the mode information and the third error correction code.

In carrying out the technology disclosed herein and according to a fifth mode thereof, there is provided a storage apparatus. The storage apparatus has a memory that is accessed by a predetermined access unit. The storage apparatus further has a first write unit generation portion configured, if a write command of a first mode is issued to the memory, to generate, as a first write unit, write data by pairing data obtained by delimiting, by a first size smaller than an access unit of the memory, write data associated with the write command of the first mode with a first error correction code for the data and attaching mode information indicative of the first mode to each pair. The storage apparatus further has a second write unit generation portion configured, if a write command of a second mode is issued to the memory, to generate, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair. The storage apparatus further has a write processing portion configured, if the write command of the first mode is issued to same memory, to write the first write unit to the memory as an access unit and, if the write command of the second mode is issued to the memory, to write the second write unit to the memory as the access unit. This novel setup allows the writing of data to the memory without waiting the generation of error correction codes in any one of the first mode and the second mode. It should be noted that, in the fifth mode, the above-mentioned memory may be a nonvolatile memory.

In carrying out the technology disclosed herein and according to a sixth embodiment thereof, there is provided an information processing system. The information processing system has a memory that is accessed by a predetermined access unit. The information processing system further has a first write unit generation portion configured, if a write command of a first mode is issued to the memory, to generate, as a first write unit, write data by pairing data obtained by delimiting, by a first size smaller than an access unit of the memory, write data associated with the write command of the first mode with a first error correction code for the data and attaching mode information indicative of the first mode to each pair. The information processing system further has a second write unit generation portion configured, if a write command of a second mode is issued to the memory, to generate, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair. The information processing system further has a write processing portion configured, if the write command of the first mode is issued to same memory, to write the first write unit to the memory as an access unit and, if the write command of the second mode is issued to the memory, to write the second write unit to the memory as the access unit. The information processing system further has a computer that issues a write command and a read command to the above-mentioned memory. This novel setup allows the writing of data to the memory as instructed by the computer without waiting for the generation of error correction codes in any one of the first mode and the second mode.

In carrying out the technology disclosed herein and according to a seventh mode thereof, there is provided a storage control method. The storage control method has the step of, if a write command of a first mode is issued to a memory, generating, as a first write unit, write data by pairing data obtained by delimiting, by a first size smaller than an access unit of the memory, write data associated with the write command of the first mode with a first error correction code for the data and attaching mode information indicative of the first mode to each pair. The storage control method further has the step of, if a write command of a second mode is issued to the memory, to generating, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair. The storage control method further has the step of, if the write command of the first mode is issued to same memory, writing the first write unit to the memory as an access unit and, if the write command of the second mode is issued to the memory, writing the second write unit to the memory as the access unit. This novel setup allows the writing of data to the memory without waiting for the generation of error correction codes in any one of the first mode and the second mode.

The present technology has a beneficial effect on flexibly setting the rules of attaching error correction codes to a group of data sequences in a memory.

### BRIEF DESCRIPTION OF THE DRAWINGS

FIG. 1 is a block diagram illustrating an exemplary configuration of an information processing system practiced as a first embodiment of the technology disclosed herein;

FIG. 2 is a diagram illustrating an exemplary outline of a memory map of a random access memory in the first embodiment shown in FIG. 1;

FIG. 3 is a block diagram illustrating an exemplary configuration of a memory shown in FIG. 1;

FIGS. 4A, 4B, and 4C are diagrams illustrating exemplary page structures in the memory shown in FIG. 1;

FIG. 5 is a diagram illustrating an exemplary configuration of a free page table shown in FIG. 2;

FIG. 6 is a diagram illustrating an exemplary configuration of an address translation table shown in FIG. 2;

FIG. 7 is a diagram illustrating an exemplary configuration of an ECC type table practiced as the first embodiment of the technology disclosed herein;

FIG. 8 is a block diagram illustrating an exemplary functional configuration of a storage control apparatus practiced as the first embodiment of the technology disclosed herein;

FIG. 9 is a diagram illustrating a relation between write data and logical page in the first embodiment shown in FIG. 1;

FIG. 10 is another diagram illustrating a relation between write data and logical page in the first embodiment shown in FIG. 1;

FIG. 11 is a flowchart indicative of an exemplary read operation of the information processing system shown in FIG. 1;

FIG. 12 is a flowchart indicative of an exemplary write operation of the information processing system shown in FIG. 1;

FIG. 13 is a flowchart indicative of an exemplary operation of a logical page partial rewrite processing of the information processing system shown in FIG. 1;

FIG. 14 is a block diagram illustrating an exemplary functional configuration of the storage control apparatus practiced as a second embodiment of the technology disclosed herein;

FIG. 15 is a block diagram illustrating an exemplary configuration of an information processing system practiced as a third embodiment of the technology disclosed herein;

FIG. 16 is a block diagram illustrating an exemplary functional configuration of a memory control section shown in FIG. 15;

FIG. 17 is a diagram illustrating an exemplary format configuration of a first write unit in the third embodiment shown in FIG. 15;

FIG. 18 is a diagram illustrating an exemplary format configuration of a second write unit in the third embodiment shown in FIG. 15;

FIG. 19 is a diagram illustrating an exemplary format configuration of mode information in the third embodiment shown in FIG. 15;

FIG. 20 is a flowchart indicative of an exemplary read processing procedure in a 32-byte mode in the third embodiment shown in FIG. 15;

FIG. 21 is a flowchart indicative of an exemplary read processing procedure in a 512-byte mode in the third embodiment shown in FIG. 15;

FIG. 22 is a flowchart indicative of an exemplary write processing procedure in the 32-byte mode in the third embodiment shown in FIG. 15; and

FIG. 23 is a flowchart indicative of an exemplary write processing procedure in the 512-byte mode in the third embodiment shown in FIG. 15.

### DETAILED DESCRIPTION OF THE PREFERRED EMBODIMENTS

The present disclosure will be described in further detail by way of embodiments thereof with reference to the accompanying drawings. The description will be done in the following order:

1. First embodiment (an example in which an ECC type is set for each logical page address)

2. Second embodiment (an example in which an ECC type is set for each physical address)

3. Variations

4. Third embodiment

5. Variations

### 1. First Embodiment

### [Configuration of Information Processing System]

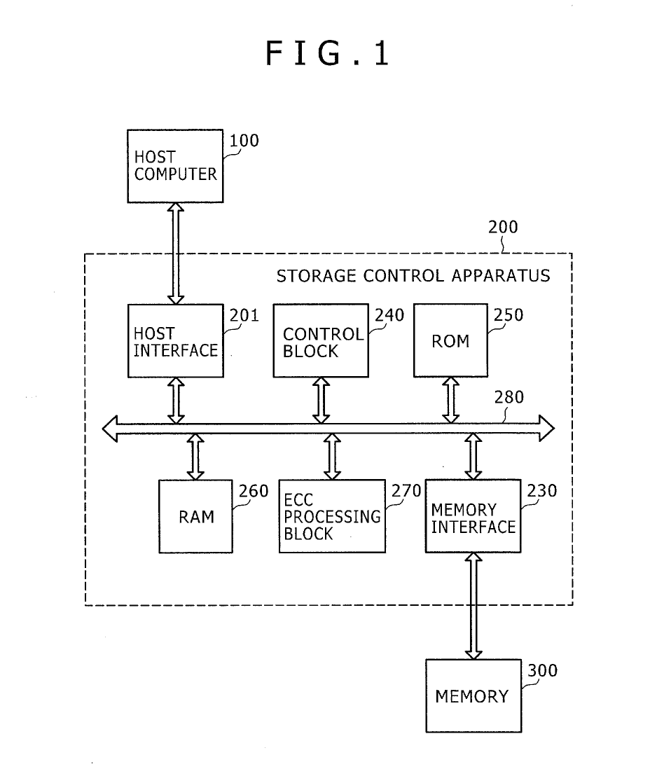

Now, referring to FIG. 1, there is shown an exemplary configuration of an information processing system practiced as a first embodiment of the technology disclosed herein. The information processing system has a host computer 100, a storage control apparatus 200, and a memory 300. The host computer 100 executes processing operations in this information processing system. The memory 300 stores data necessary for the host computer 100 to execute the processing operations. For this memory 300, a nonvolatile memory is assumed. The memory 300 stores an error correction code (ECC) along with data to improve data retention characteristics. The storage control apparatus 200 is connected between the host computer 100 and the memory 300 to control the memory 300 in accordance with requests from the host computer 100. It should be noted that the error correction code also has an error detection function, so that the error correction code is also sometimes referred to as an error detection code.

The storage control apparatus 200 has a host interface 201, a memory interface 230, a control block 240, a read only memory (ROM) 250, a random access memory (RAM) 260, and an ECC processing block 270. These component blocks are interconnected via a bus 280.

The host interface 201 is an interface circuit for providing interface with the host computer 100. The memory interface 230 is an interface circuit for providing interface with the memory 300.

The control block 240 is a processing apparatus for executing various processing operations in the storage control apparatus 200. The ROM 250 is a read-only memory for storing programs to be executed by the control block 240 and parameters necessary for this execution. The RAM 260 is a memory for providing a work area necessary for the control block 240 to execute the processing operations.

The ECC processing block 270 executes the processing associated with error correction codes stored in the memory 300. The ECC processing block 270 includes a function of generating error correction codes and a function of executing error correction by use of the data and error correction code read from the memory 300, which will be described later.

An access space of the memory 300 is partitioned into a fixed-length physical pages to be managed. Each of the physical pages of the memory 300 is mapped to a logical page. The memory 300 is accessed by the host computer 100 basically by logical address. In the following description, the data size of each logical page is assumed to be 256 bytes and 256-byte data and a 16-byte error correction code be stored in each physical page. It should be noted however that these sizes are illustrative only and therefore the technology disclosed herein is not limited thereto.

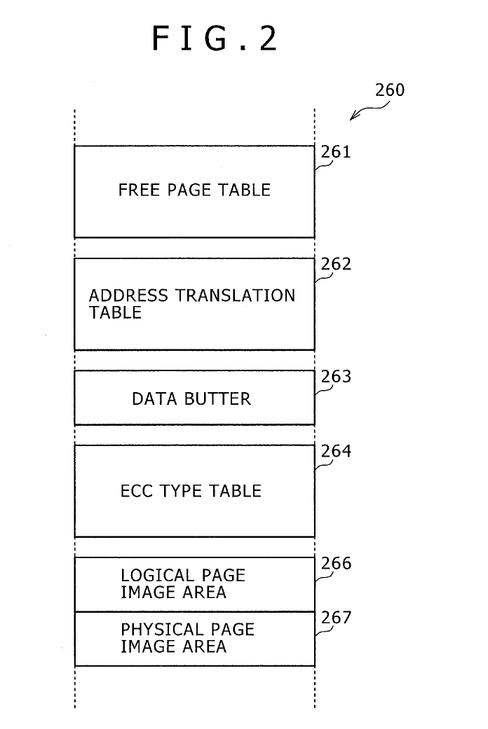

Referring to FIG. 2, there is shown an exemplary outline of a memory map of the RAM 260 practiced as the first embodiment of the technology disclosed herein. In this example, the RAM 260 stores a free page table 261, an address translation table 262, a data buffer 263, an ECC type table 264, a logical page image area 266, and a physical page image area 267. It should be noted that programs to be executed by the control block 240 and an area for use by this execution are also stored in the RAM 260.

The free page table 261 manages a physical page usage status in the memory 300. The free page table 261 holds the usage status of physical pages corresponding to physical page addresses, which will be detailed later.

The address translation table 262 translates a logical address supplied from the host computer 100 into a physical address in the memory 300. The address translation table 262 holds physical page addresses corresponding to logical pages, which will be detailed later. It should be noted that the address translation table 262 is one example of an address translation block cited in the scope of claims herein.

The data buffer 263 holds write data that is transmitted from the host computer 100 to the memory 300. In the first embodiment, it is assumed that the data buffer 263 hold data of which size is equal to the maximum size of the write data making up a write command issued from the host.

The ECC type table 264 manages the types of error correction codes by page. The ECC type table 264 holds error correction code types (ECC types) of pages corresponding to logical page addresses, which will be detailed later. The error correction code types will be described later. It should be noted that the ECC type table 264 is one example of an error correction code attachment rules hold block cited in the scope of claims herein.

The logical page image area 266 is an area for holding an image of a logical page grasped by the host computer 100. The physical page image area 267 is an area for holding an image of a physical page on the side of the memory 300. In the first embodiment, the logical page image area 266 is an area of 256 bytes that is equal to the size of each logical page and the physical page image area 267 is an area of 272 bytes that is equal to the size of each physical page.

The three types of tables, the free page table 261, the address translation table 262, and the ECC type table 264, are stored at predetermined locations in the memory 300 while the power to the storage control apparatus 200 is off. In the initialization processing to be executed upon turning on the power, the storage control apparatus 200 reads these three types of tables from the predetermined locations in the memory 300 and temporarily stores these tables in the RAM 260. When a power shutoff advance alert comes from the host computer 100, the storage control apparatus 200 writes these three types of tables to the predetermined locations in the memory 300. In order to minimize the influence of an unexpected power shutoff, the storage control apparatus 200 writes these three types of tables at certain intervals or every time a certain number of processing operations have completed.

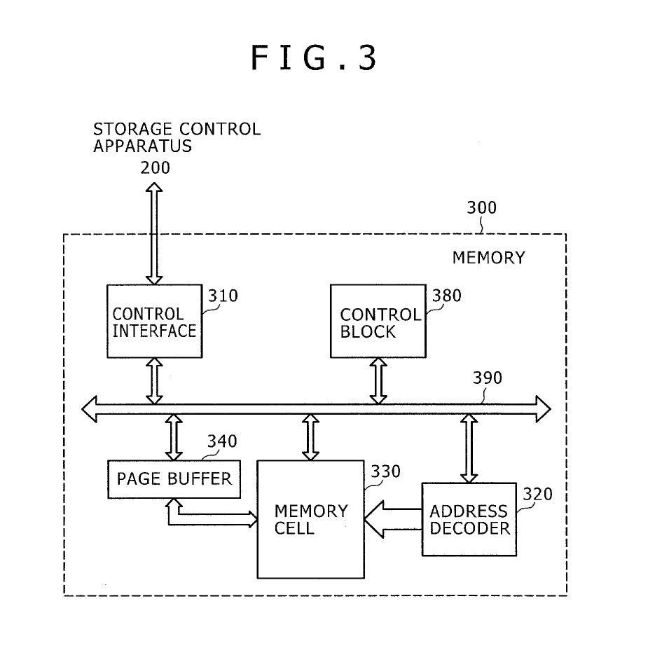

Referring to FIG. 3, there is shown an exemplary configuration of the memory 300 in the first embodiment shown in FIG. 1. The memory 300 has a control interface 310, an address decoder 320, a memory cell 330, a page buffer 340, and a control block 380. These component blocks are interconnected via a bus 390.

The control interface 310 is an interface circuit for providing interface with the storage control apparatus 200. The control interface 310 enters information and data transmitted from the storage control apparatus 200 and outputs information and data to be transmitted to the storage control apparatus 200.

The memory cell 330 is a storage device, which is assumed to be a nonvolatile memory herein. The memory cell 330 has a structure in which unitary memory cells each recording 1-bit data are arranged two-dimensionally. For example, the memory cell 330 is configured by vertically arranging along physical page addresses the unitary memory cells for 272 bytes of a physical page arranged horizontally.

The address decoder 320 decodes a physical page address entered from the control interface 310 to drive one word line corresponding to one physical page of the address. Between the address decoder 320 and the memory cell 330, word lines corresponding to all physical pages are wired. The physical page corresponding to a word line driven in the memory cell 330 becomes active.

The page buffer 340 has the same size as that of each physical page in the memory cell 330. The page buffer 340 transfers data with the physical page made active in the memory cell 330.

The control block 380 controls the memory 300 in its entirety. If an instruction issued by the storage control apparatus 200 is a write operation, then the control block 380 supplies a physical address transferred to the control interface 310 to the address decoder 320 to activate the specified physical page on the memory cell 330. Further, the control block 380 supplies write data transferred to the control interface 310 to the page buffer 340 to instruct the memory cell 330 for a write operation. Consequently, data is written to the active physical page.

If an instruction issued by the storage control apparatus 200 is a read operation, then the control block 380 enters a physical address transferred to the control interface 310 into the address decoder 320 to activate the specified physical page on the memory cell 330. Further, the control block 380 instructs the memory cell 330 for a read operation. Consequently, the active physical page is read to be supplied to the page buffer 340. The control block 380 supplies the data read into the page buffer 340 to the control interface 310 to transfer the data to the storage control apparatus 200 via the control interface 310.

It should be noted that, in the following description, each logical address specified by the host computer 100 and each logical page address handled in the storage control apparatus 200 are expressed by hexadecimal notation starting with “0x” and each physical page address is expressed by decimal notation.

### [Page Structure]

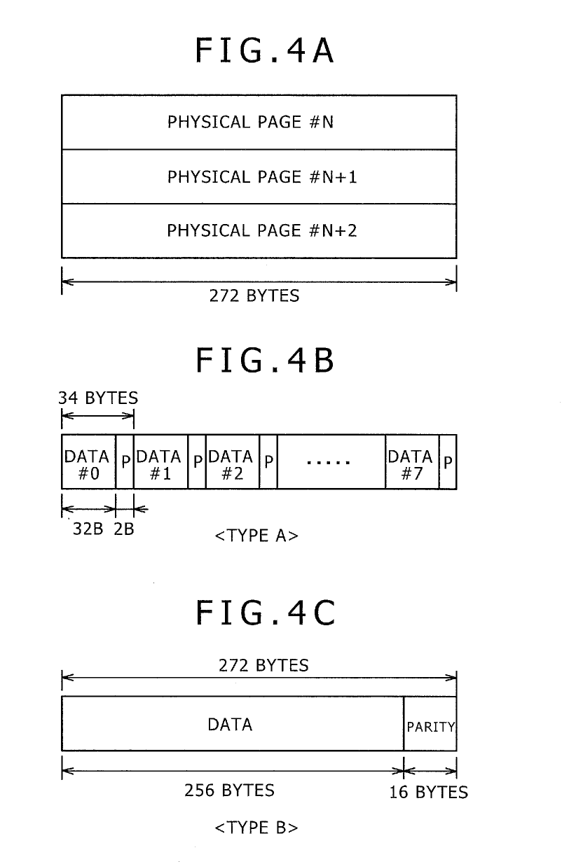

Referring to FIGS. 4A through 4C, there is shown one example of a page structure in the memory 300 in the first embodiment of the technology disclosed herein. As shown in FIG. 4A, in the first embodiment, the size of each physical page stored in the memory cell 330 is 272 bytes. When storing 256-byte data and a 16-byte error correction code (or a parity) into this physical page, the following two types are assumed as error correction code attachment rules.

In type A, a 272-byte physical page is divided into 34-byte sub pages as shown in FIG. 4B, each being used as 32-byte data and a 2-byte parity. On the other hand, in type B, a 272-byte physical page is used as 256-byte data and a 16-byte parity as shown in FIG. 4C. Which of these two types is to be used as error correction code attachment rules is controlled by the ECC type table 264. It should be noted that the 256-byte data of one page is one example of a group of data sequences cited in the scope of claims herein. Further, the 32-byte data of each of the sub pages obtained by dividing one page is one example of a partial data sequence cited in the scope of claims herein.

The type A structure has eight independent sub pages, so that, depending on the performance of the ECC processing block 270, eight sub pages can be simultaneously processed to enhance the speed of error correction code generation processing and error correction processing. In addition, type B has a relatively long word length, so that, as compared with type A, type B takes a longer computation time but can enhance the reliability of data retention by use of low density parity check (LDPC) coding that is comparatively large in computation quantity.

In FIG. 4B, it is assumed that 32-byte data and 2-byte parity be recorded side by side as one example of type A page structure. However, the memory cell features allow, these data may be divided by a desired format. For example, 2-byte parity may be recorded in a remote area collectively.

The ECC type specification is executed by a write command for example. In this case, the specification may be done by a particular field in a write command or by another command as required. In addition, an independent command for setting an ECC type may be separately arranged. For example, the ECC type setting command may be executed immediately before an important file is written and then a normal write command may be executed, thereby executing a write operation by the ECC type set by the ECC type setting command.

### [Table Configuration]

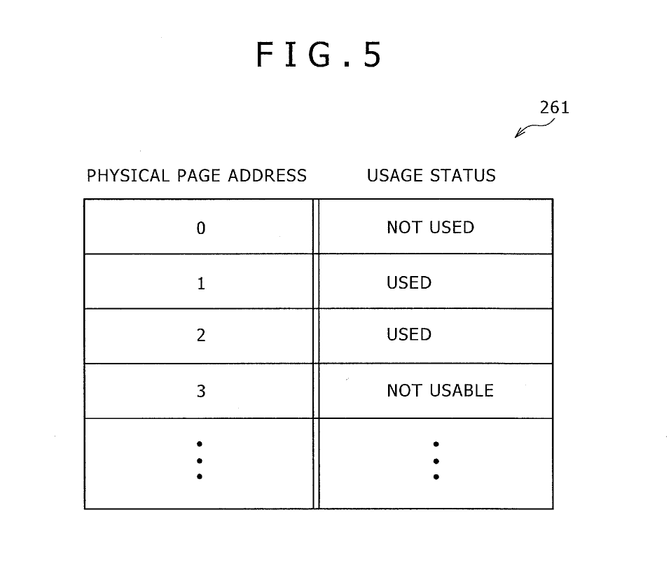

Referring to FIG. 5, there is shown an exemplary configuration of the free page table 261 in the first embodiment of the technology disclosed herein. The free page table 261 holds a usage status of physical pages respectively corresponding to physical page addresses. Each of the entries (rows) of free page table 261 is made up of two elements; physical page address and usage status.

In the free page table 261, the physical page status indicated in the physical page address column of each entry is indicated in the usage status column. The usage status here denotes any one of the three statuses; “not used” where no physical page in the memory cell 330 is used, “used” where physical pages are in use, and “not usable” where physical pages are not currently in use and not recommended to be used in the future by reason of an error or the like.

In the free page table 261, the entries are arranged in the ascending order of the values of physical page addresses. The number of entries registered in the free page table 261 is equal to the number of physical pages arranged in the memory cell 330 of the memory 300.

It should be noted that the values of physical page addresses in the free page table 261 increment by one starting with zero and therefore can easily be computed from entry numbers. Therefore, it is also practicable delete the physical page addresses column from the entry columns to make the entry configuration element be made up only by the usage status column.

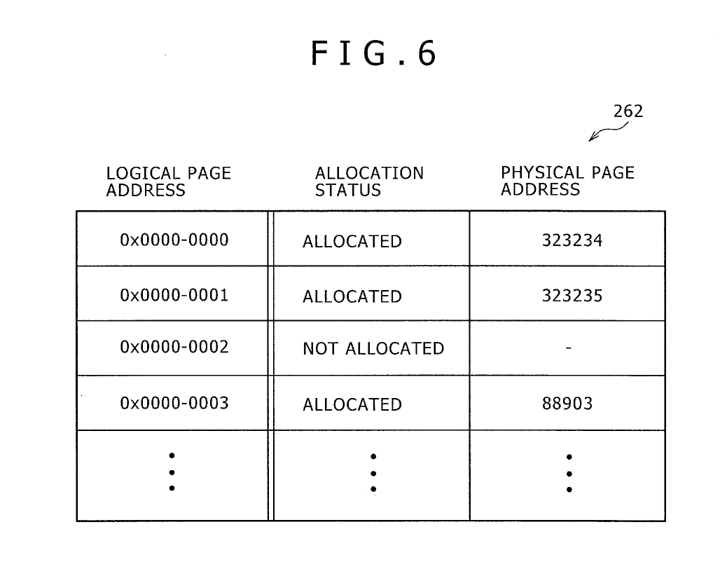

Referring to FIG. 6, there is shown an exemplary configuration of the address translation table 262 in the first embodiment of the technology disclosed herein. The address translation table 262 holds physical page addresses respectively corresponding to logical page addresses. To be more specific, the address translation table 262 shows a correlation between the logical addresses for use with the host computer 100 and the physical addresses for use in the storage control apparatus 200 and the memory 300.

In the storage control apparatus 200 in the first embodiment, logical addresses specified from the host computer 100 are managed on a logical page address basis. Here, logical pages are related with physical pages on a one-to-one basis, in which one physical page is allocated to one logical page. The size of each logical page is 256 bytes, which are equal to the 256 bytes of the total pieces of data in each physical page. A logical page address is obtained by dividing the logical address specified from the host computer 100 by logical page size, the remainder of this division being an offset address in the logical page.

Each of the entries of the address translation table 262 is made up of three elements; logical page address, allocation status, and physical page address. The logical page indicated in the logical page address column of each entry indicates “allocated” where a physical page is allocated and “not allocated” where no physical page is allocated. For the logical page with the allocation status column being “allocated,” the address of the corresponding physical page is indicated in the physical page address column.

In the example shown in FIG. 6, in the entry with logical page address column being “0x0000-0002,” the allocation status column is “not allocated,” so that the value shown in the physical page address is insignificant. Hence, the value in the physical page address column for this entry shows “-.”

In the address translation table 262, the entries are arranged in the ascending order of the values of logical page addresses. The number of entries registered in the address translation table 262 is equal to a value obtained by dividing the size (in unit of bytes) of the logical address space made public for the host computer 100 by the storage control apparatus 200 by 256 bytes that is the size of each logical page.

The number of entries registered in the address translation table 262 is smaller than that of the physical pages arranged in the memory cell 330 of the memory 300. This is because, as described above in the description of the free page table 261, the number of physical pages has a margin that is large enough for the number of logical pages in order to prevent the physical pages from becoming unavailable due to an error or the like.

It should be noted that the values of the logical page addresses in the address translation table 262 increment by one starting with zero and therefore can easily be computed from entry numbers. Therefore, it is also practicable to delete the logic page address column to make the entry configuration elements be made up by the allocation status column and the physical page address column.

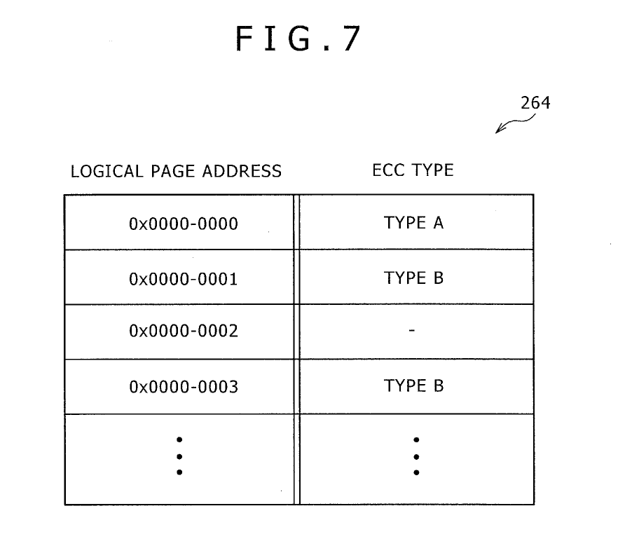

Referring to FIG. 7, there is shown an exemplary configuration of the ECC type table 264 in the first embodiment of the technology disclosed herein. The ECC type table 264 holds the error correction code types (ECC types) for the pages corresponding to logical page addresses.

Each of the entries of the ECC type table 264 is made up of two elements; logical page address and ECC type. The ECC type indicates whether the error correction code attachment rules in the logical page corresponding to the logical page address column in each entry are of type A or type B.

In the ECC type table 264, the entries are arranged in the ascending order of the values of logical page addresses. The number of entries registered in the ECC type table 264 is equal to a value obtained by dividing the size (in unit of bytes) of the logical address made public to the host computer 100 by the storage control apparatus 200 by 256 bytes that are the size of each logical page.

It should be noted that the values in the logical page address column of the ECC type table 264 increment by one starting with zero and therefore can be easily computed from entries (or rows). Therefore, it is also practicable to delete the logical page address column from the entry to make the entry configuration element be made up only by the ECC type.

Like the address translation table 262, the number of entries registered in the ECC type table 264 is smaller than that of physical pages arranged in the memory cell 330 of the memory 300.

### [Functions of the Storage Control Apparatus]

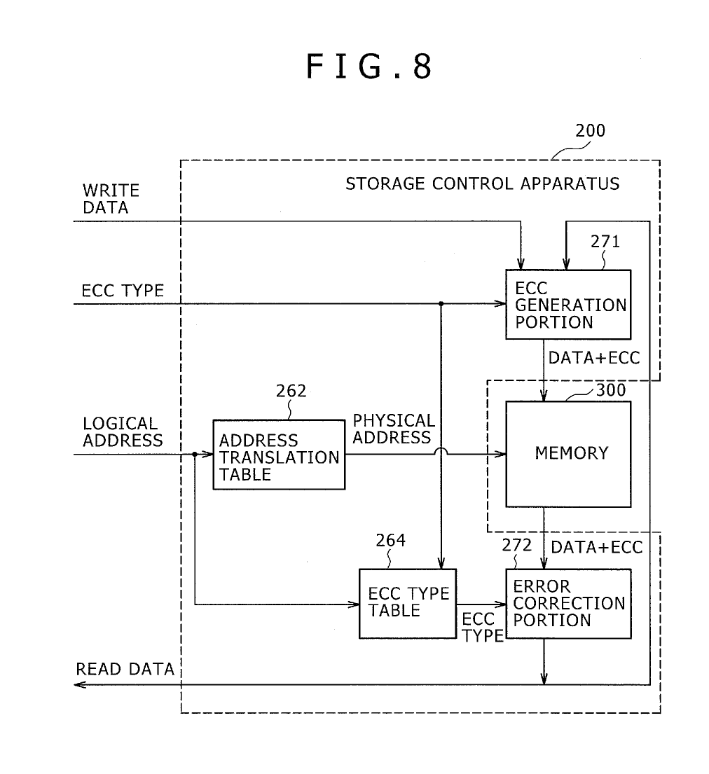

Referring to FIG. 8, there is shown an exemplary functional configuration of the storage control apparatus 200 in the first embodiment of the technology disclosed herein. In this example, the address translation table 262 and the ECC type table 264 described above are shown. In addition, for parts of the ECC processing block 270, an ECC generation portion 271 and an error correction portion 272 are shown.

The ECC generation portion 271 generates an error correction code in accordance with an ECC type specified at the time of a write operation. If data to which error correction codes are attached is all included in write data, then the ECC generation portion 271 generates an error correction code by use of the write data of a write command (or a write request). On the other hand, if it is necessary to generate an error correction code along with data other than write data, then the ECC generation portion 271 generates a error correction code also by use of data read from the memory 300. The error correction codes generated by the ECC generation portion 271 are stored in the memory 300 along with the data. The write address used at the time of the storing the generated error correction code is a physical address supplied from the address translation table 262. At the same time, the ECC type specified at the time of a write operation is held in the entry corresponding to the logical address that is write address of a write command in the ECC type table 264. It should be noted that the ECC generation portion 271 is one example of an error correction code generation portion cited in the scope of claims herein.

The error correction portion 272 execute error correction by use of data and an error correction code read from the memory 300. The error correction code attachment rules for use at the execution of error correction are supplied from the ECC type table 264. The ECC type table 264 outputs an ECC type on the basis of a logical address that is the read address of a read command. It should be noted that a read address used in the memory 300 is a physical address supplied from the address translation table 262. In accordance with the ECC type outputted from the ECC type table 264, the error correction portion 272 executes error detection and, if necessary, error correction, outputting resultant data. The outputted data is returned to host computer 100 as read data or supplied to the ECC generation portion 271 as data making a physical page along with write data. It should be noted that the error correction portion 272 is one example of an error correction portion cited in the scope of claims herein.

### [Relation Between Write Data and Logical Pages]

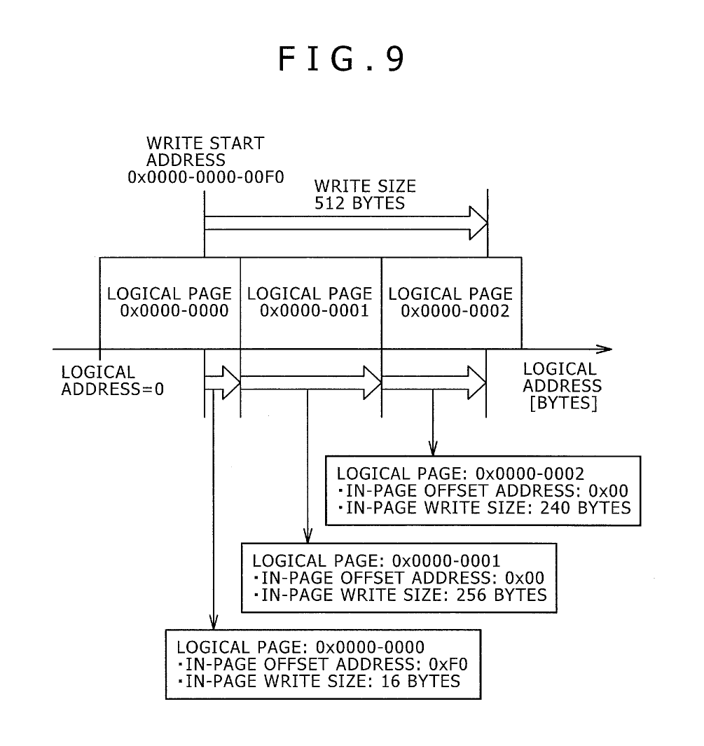

Referring to FIG. 9, there is shown the relation between write data and logical pages in the first embodiment of the technology disclosed herein. In this example, the start logical address of a write command is “0x0000-0000-00F0” and write size is 512 bytes. To be more specific, this write command writes data over three logical pages, from “0x0000-0000” to “0x0000-0002.”

The processing of a write command is executed on a logical page basis, so that the logical page must be resolved (or divided) into three logical pages as shown in FIG. 9. In logical page “0x0000-0000,” the in-page offset address at write start position is “0xF0” and the in-page write size is 16 bytes. In logical page “0x0000-0001,” the in-page offset address at write start position is “0x00” and the in-page write size is 256 bytes. In logical page “0x000-0002,” the in-page offset address at write start position is “0x00” of the beginning and the in-page write size is 240 bytes.

If the in-page offset address is different from “0x00” as with logical page “0x0000-0000” of this example, rewrite does not occur at the beginning of that logical page. If the in-page offset address is “0x00” and the in-page write size is less than 256 bytes as with logical page “0x0000-0002,” write does not occur at the end of that logical page.

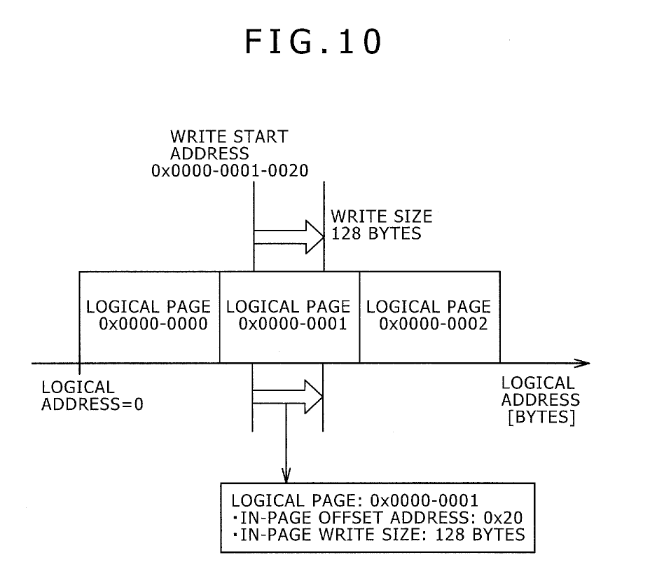

Referring to FIG. 10, there is shown another diagram for describing a relation between write data and logical pages in the first embodiment of the technology disclosed herein. In this example, the start logical address of a write command is “0x0000-0001-0002” and the write size is 128 bytes. To be more specific, this write command is smaller than the size of the logical page, does not extend over two or more logical pages, and writes data only to a part of logical page “0x0000-0001.”

In this case, in logical page “0x0000-0001,” in-page offset address at write start position is “0x20” and the in-page write size is 128 bytes. If the in-page offset address is other than 0 and the in-page write size is less than 256 bytes as with logical page “0x0000-0001” in this example, write occurs halfway in the logical page.

### [Operations of the Information Processing System]

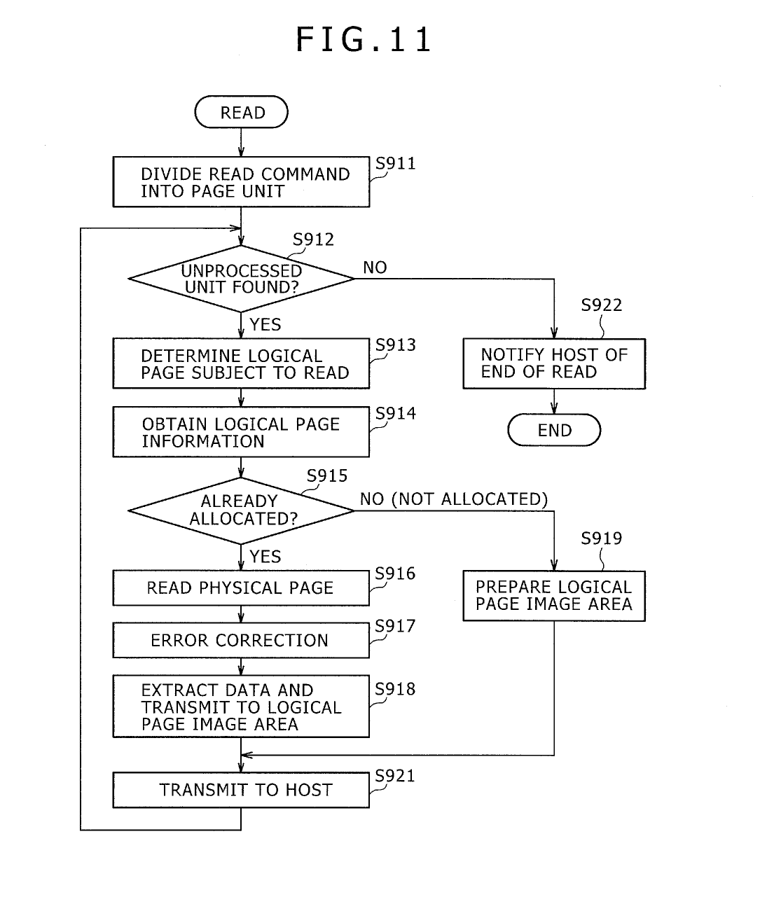

Referring to FIG. 11, there is shown a flowchart indicative of an exemplary read operation of the information processing system in the first embodiment of the technology disclosed herein. First, a read command (or a read request) issued by the host computer 100 is entered in the storage control apparatus 200 via the host interface 201. The read command is made up of a read address and a read data size. The read address is a logical address of the data to be read.

The control block 240 divides the read address and the read data size making up the read command into logical page units (step S911). To be more specific, this is substantially the same as the division on a logical page basis in a write operation described above with reference to FIG. 9 and FIG. 10. Consequently, an in-page offset address and an in-page read size can be obtained by computation for each logical page.

Then, it is determined whether or not, among the logical page units divided in step S911, there is any logical page unit not processed for read processing (step S912). If no logical page unit not processed for read processing is found (step S912: No), then the host computer 100 is notified of the termination of the processing of the read command, upon which the read operation ends (step S922).

On the other hand, if any logical page units not processed for read processing are found (step S912: Yes), then one of the logical page units not processed for read processing is selected (step S913). Here, it is assumed that the selection be executed in the ascending order of logical page addresses. Then, information about the logical page corresponding to the read processing of the selected logical page unit is obtained from the address translation table 262 and the ECC type table 264 (step S914).

Next, it is checked whether a physical page is allocated to the logical page to be processed (step S915). To be more specific, if the allocation status is “not allocated,” then the procedure goes to step S919; if the allocation status is “allocated,” then the procedure goes to step S916.

If the allocation status is “not allocated” (step S915: No), it indicates that the physical page corresponding to the logical page to be read is not allocated, so that the data to be transmitted to the host computer 100 is prepared (step S919). To be more specific, the logical page image area 266 is cleared to zero. It is also practicable to do initialization by use of periodic data such as “0x00” or “0xFF” for example or predetermined specific data rather than zero clear. In this example, initialization is done every time step S919 is passed, but it is also practicable to arrange a special area in the RAM 260 for doing initialization at the time of power-on sequence for example to transmit the data in this special area to the host computer 100 when a read command comes for reading the logical page to which no physical page is allocated.

It is also practicable to read a physical page allocated in the memory 300 for the read to a logical page to which no physical page is allocated and transfer the this allocated physical page to the host computer 100. By writing to the allocated physical page in advance, the data different from memory to memory can be transferred to the host computer 100.

If the allocation status is “allocated” (step S915: Yes), then the data corresponding to this logical page is read (step S916). The physical page address at this time is the physical page address read from the address translation table 262 in step S914. At this time, the storage control apparatus 200 issues a read command and transmits the physical page address to the memory 300. The memory 300 reads the contents of the physical page corresponding to the specified physical page address and transfers the contents of the physical page to the storage control apparatus 200. The storage control apparatus 200 stores the data of the physical page received from the memory 300 into the physical page image area 267.

Next, the error correction portion 272 of the ECC processing block 270 executes error correction (step S917). In doing so, the error correction portion 272 is given with an ECC type obtained from the ECC type table 264 in step S914, the start address of the physical page image area 267, and an error correction command. If ECC type is type A, the error correction portion 272 reads 34 bytes from the start address of the physical page image area 267 and interprets that a 2-byte parity is attached to the 32-byte user data, thereby executing error correction. Then, the error correction portion 272 writes a result of the error correction processing back to the same location in the physical page image area 267. The processing is executed eight times to complete the error correction processing. On the other hand, if type B is specified for ECC type, then the error correction portion 272 read 272 bytes from the start address of the physical page image area 267 and interprets that a 16-byte parity is attached to the 256-byte user data, thereby executing error correction processing. Then, the error correction portion 272 writes a result of the error correction processing back to the same location in the physical page image area 267.

Then, the control block 240 extracts data from the physical page image area 267 and transfers the extracted data to the logical page image area 266 (step S918). To be more specific, if type A is specified for ECC type, then 32 bytes from the beginning of the physical page image area 267 and these 32 bytes are transferred to the logical page image area 266, thereby skipping the read processing by two bytes. The processing is repeated eight times to terminate the extraction of user data. On the other hand, if type B is specified for ECC type, then 256 bytes are read from the beginning of the physical page image area 267 and these 256 bytes are transferred to the logical page image area 266.

When the logical page image area 266 is prepared as described above (step S918 or S919), the data of the logical page image area 266 is transferred to the host computer 100 (step S921). Namely, the data is transferred from the location of an in-page offset address of the logical page image area 266 by an amount of an in-page read size. The in-page offset address and the in-page read size are those computed in step S911. Then, the above-mentioned processing from step S912 is repeated.

It should be noted that, in the first embodiment, data copy is executed in the data extraction processing (step S918) and the processing of transfer to the host computer 100 (step S921); it is also practicable to transfer data immediately from the physical page image area 267.

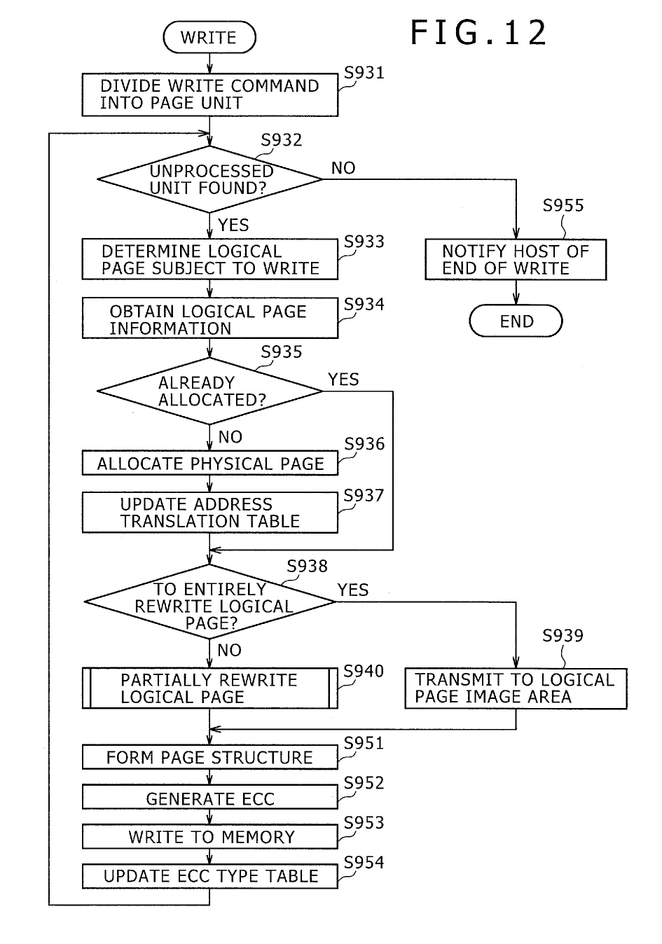

Referring to FIG. 12, there is shown a flowchart indicative of an exemplary operation of the information processing system in the first embodiment of the technology disclosed herein. First, a write command (or a write request) issued by the host computer 100 is entered in the storage control apparatus 200 via the host interface 201. The write command is made up of a write address, an ECC type, a write data size, and write data. The write data is temporarily stored in the data buffer 263 of the RAM 260. The write address is a logical address of the data to be written.

The control block 240 divides the write address and the write data size making up a write command into logical page units as described above (step S931). Consequently, an in-page offset address and an in-page write size are obtained for each logical page. In addition, the control block 240 computes all start addresses of the areas with the write data given from the host computer 100 and temporarily stored in the data buffer 263 resolved for each logical page. The division into logical page units is as described above with reference to FIG. 9 and FIG. 10. In the processing of step S932 and on is executed repeatedly on the logical page units divided in step S931.

Then, it is determined whether or not, among the logical page units divided in step S931, there is any logical page unit not processed for write processing (step S932). If no logical page unit not processed for write processing is found (step S932: No), then the host computer 100 is notified of the termination of the processing of the write command, upon which the write operation ends (step S955).

On the other hand, if any logical page units not processed for write processing are found (step S932: Yes), then one of the logical page units not processed for write processing is selected (step S933). Here, it is assumed that the selection be executed in the ascending order of logical page addresses. Then, information about the logical page corresponding to the write processing of the selected logical page unit is obtained from the address translation table 262 and the ECC type table 264 (step S934).

Next, it is checked whether or not a physical page is allocated to the logical page to be processed (step S935). To be more specific, if the allocation status is “not allocated,” then the procedure goes to step S938; if the allocation status is “allocated,” then the procedure goes to step S936.

If the allocation status is “not allocated,” a usable physical page is allocated on the basis of the free page table 261 (step S936). To be more specific, an entry with usage status being “not used” is searched for and, if such an entry is found, value of “in use” is substituted into the usage status. It should be noted that if no usable physical page is found in the free page table 261, the host computer 100 is notified thereof, the description of which is omitted here.

When a physical page is allocated, the allocation status is changed to “allocated” in the corresponding entry in the address translation table 262 and, at the same time, the allocated physical page address is set to the physical page address (step S937). Further, the information that the logical page being processed has been newly allocated is recorded to a new page flag that is an internal variable.

Next, it is determined whether or not a write operation to the logical page being processed is to rewrite the logical page in its entirety (step S938). To be more specific, if, in the processing for the logical page being processed, the value of write data size of the divided logical page unit is equal to “256,” then it is determined that the logic page is entirely rewritten (step S938: Yes). On the other hand, if the value of write data size of the divided logical page unit is not equal to “256,” then it is determined that the logic page is partially rewritten (step S938: No).

If the write operation to the logical page being processed is to rewrite the entire logical page (step S938: Yes), then the data of the data buffer 263 is transferred to the logical page image area 266 (step S939). To be more specific, 256 bytes for the number of logical pages are transferred to the logical page image area 266 from the start addresses of areas with the write data temporarily stored in the data buffer 263 resolved for each logical page. It should be noted that the start address of each area is that computed in step S931.

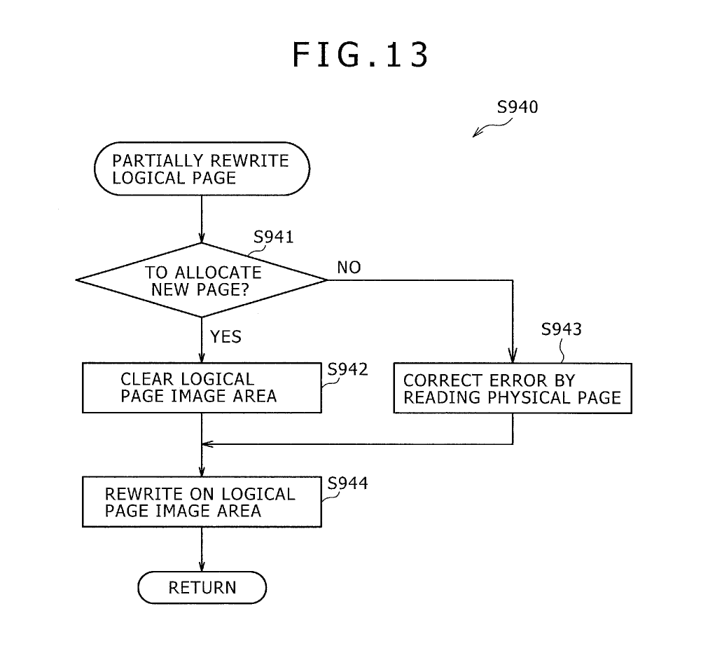

If the write operation to the logical page being processed is not to rewrite the entire logical page (step S938: No), then the logical page is partially rewritten (step S940). The following describes this partial rewrite of a logic page with reference to FIG. 13.

Referring to FIG. 13, there is shown a flowchart indicative of an exemplary operation of the logical page partial rewrite processing of the information processing system in the first embodiment of the technology disclosed herein. First, a new page flag is checked (step S941). To be more specific, if the execution of new allocation in step S937 is recorded to the new page flag (step S941: Yes), the logical page image area 266 is cleared (step S942).

On the other hand, if the execution of new allocation is not recorded to the new page flag (step S941: No), then the data corresponding to the logic page to be written is read (step S943: No). For the physical page address at this time, information read from the address translation table 262 in step S934 can be used. The contents of the physical page read here are reflected onto the physical page image area 267 and error correction is executed by the error correction portion 272 in the physical page image area 267. Next, the data part is extracted from the physical page image area 267 to be transferred to the logical page image area 266.

Subsequently, a partial write operation is executed in the logical page image area 266 (step S944). To be more specific, a rewrite operation for the in-page write size is executed from the location of the in-page offset address in the logical page image area 266. The in-page offset address and the in-page write size are those computed in the step S931.

With reference to FIG. 12 again, the physical page image area 267 is formed on the basis of the logical page image area 266 prepared by the processing described so far (step S951). To be more specific, If type A is specified for ECC type, then 32 bytes are read from the beginning of the logical page image area 266 and these 32 bytes are transferred to the physical page image area 267, thereby skipping the write position by two bytes of parity. The processing is repeated eight times to terminate the forming of the page structure. On the other hand, if type B is specified for ECC type, then 256 bytes are read from the beginning of the logical page image area 266 and these 256 bytes are transferred to the physical page image area 267.

Next, the ECC generation portion 271 of the ECC processing block 270 executes error correction code generating processing (step S952). In doing so, the ECC type obtained as a parameter of a write command, the start address of the physical page image area 267, and an instruction for generating an error correction code (parity) are given from the host computer 100 to the ECC generation portion 271. If type A is specified as ECC type, the ECC generation portion 271 reads 32 bytes from the beginning of the physical page image area 267, computes a 2-byte parity, and writes the computed 2-byte parity back to the physical page image area 267, thereby completing a 34-byte sub page. The processing is repeated eight times to complete the physical page image area 267. On the other hand, if type B is specified for ECC type, then 256 bytes are read from the beginning of the physical page image area 267, a 16-byte parity is computed, and the computed 16-byte parity is written back to the physical page image area 267, thereby completing the physical page image area 267.

The contents of the physical page image area 267 completed as described above are written to the memory 300 (step S953). In doing so, the control block 240 outputs a write command and a physical page address to the memory 300 via the memory interface 230. Here, the physical page address is the address of the physical page read in step S943 or the physical page newly allocated in step S936. The memory 300 writes the received write data to the physical page specified by the physical page address.

Then, the control block 240 writes the ECC type received as a parameter of the write command from the host computer 100 to the entry corresponding to the write address of the ECC type table 264 to update the ECC type table 264 (step S954).

It should be noted that the writing to the memory 300 and the updating of the ECC type table 264 in step S953 and step S954 respectively may be executed in any sequence; these processing operations may be executed one before or after the other or concurrently. When these processing operations are completed, the procedure returns to step S932 to repeat the above-mentioned processing therefrom.

As described above, according to the first embodiment of the technology disclosed herein, an ECC type can be defined for each logical page in the ECC type table 264 as desired. The setting of the ECC types can be specified by use of a write command issued by the host computer 100, so that the reliability of the write data can be defined as desired. To be more specific, the determination from the viewpoint of the host computer 100 can be applied to the storing of data independently of a predetermined fixed pattern or the conditions of a memory chip.

### 2. Second Embodiment

### [Functions of the Storage Control Apparatus]

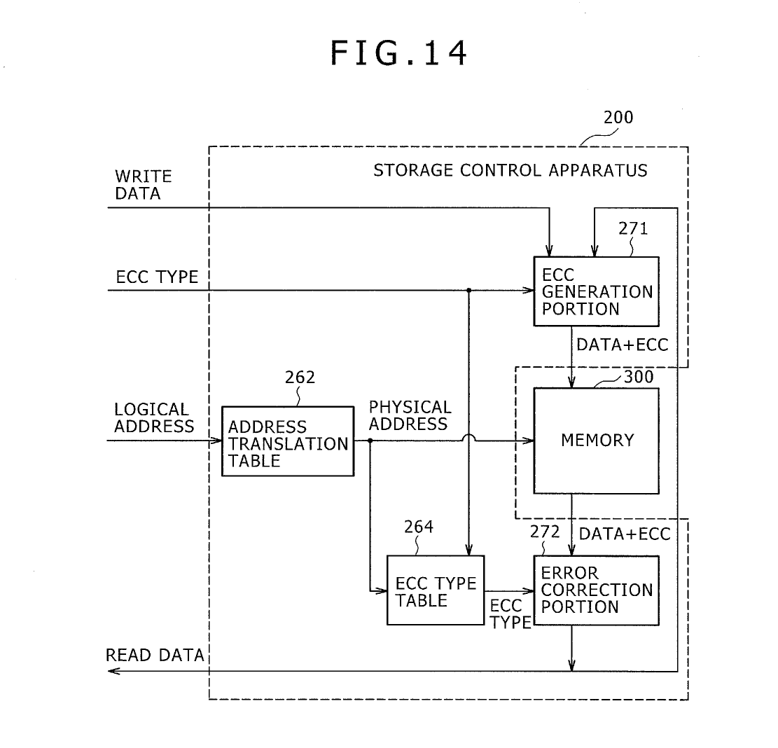

Referring to FIG. 14, there is shown an exemplary functional configuration of the storage control apparatus 200 in the second embodiment of the technology disclosed herein. The second embodiment differs from the first embodiment in that addresses to be supplied to the ECC type table 264 are physical addresses; in the other points, the second embodiment is substantially the same in functional configuration as the first embodiment.

To be more specific, in the first embodiment, an ECC type is held for each logical page address in the ECC type table 264 as shown in FIG. 7; in the second embodiment, an ECC type is held for each physical page address. Hence, the addresses to be supplied to the ECC type table 264 are physical page addresses. Consequently, in the second embodiment, an ECC type can be defined for each physical page in the ECC type table 264 as desired.

### 3. Variations

### [Skipping the Error Correction Code Recomputation in Partial Rewriting]

In the case of partial rewriting for a page to which type A is specified as ECC type, for the sub pages that are not affected by the rewriting, the error correction code need not be recomputed from the beginning. Therefore, in the present variation, error correction code recomputation is not executed in step S952 for the sub pages that are not affected by the rewriting in the partial rewriting mentioned above. In this case, the data read in step S943, error-corrected, and stored in the physical page image area 267 can be used without change. It should be noted that this data can be used under conditions that this rewriting is the partial rewriting of an existing logical page rather than new allocation and there is no change in ECC type.

To be more specific, in the present variation, if ECC type of a logical page read in step S943 is type A, the information thereof is left as an existing-page partially rewritable flag. Then, if ECC type of a write command is type A and the existing-page partially rewritable flag is valid in generating an error correction code in step S952, the following processing is executed on each sub page. Namely, before an error correction code is executed, it is determined whether or not a sub page has been rewritten. For the sub pages not included in an in-page rewrite range, error correction code generation processing and the output of these sub pages to the physical page image area 267 are skipped. For the sub pages included in the in-page rewrite range, error correction code generation processing is executed and these sub pages are outputted to the physical page image area 267.

Consequently, data with an error correction code recomputed and overwritten is prepared in the physical page image area 267 only for those sub pages which are associated with the partial rewrite range.

### [Skipping Error Correction in Partial Read Processing]

If ECC type of each logical page being processed is type A, only sub pages to be read may be error-corrected, thereby skipping error correction for the other sub pages. To be more specific, if type A is specified as ECC type in the execution of error correction processing in step S917, the following processing is executed on each sub page. Namely, before the execution of error correction processing on each sub page, it is determined whether or not the transfer of each sub page is requested. If the sub page concerned is not included in the in-page read range, error correction processing on that sub page is skipped. On the other hand, if each sub page is included in the in-page read range, error correction processing is executed on these sub pages.

Consequently, the data with error correction processing executed only on the sub pages included in the partial read range is prepared in the physical page image area 267.

### [Transfer in Sub Page Units]

If ECC type of each logical page being processed is type A, then the error-corrected sub pages may be sequentially transferred to the host computer 100. To be more specific, in the above-mentioned embodiment, error correction processing (step S917), data extraction (step S918), and transfer to the host computer 100 (step S921) are sequentially executed on a logical page basis; it is also practicable to execute these processing operations on a sub page basis. This enhances the speeds of these processing operations.

Further, combining the transfer in sub page units with the skipping of the error correction processing in the partial read operation described above allows error correction processing, data extraction, and transfer to the host computer 100 only when the transfer to the host computer 100 occurs on a sub page basis.

The sequence of processing procedures described in the embodiment mentioned above may be understood as a method having these sequence of procedures or a computer program for making a computer execute the sequence of procedures or a recording media storing such a computer program. For the recording media, a CD (Compact Disc), an MD (MiniDisc), a DVD (Digital Versatile Disk), a memory card, a Blu-ray disc (registered trademark), or the like may be available.

### 4. Third Embodiment

### [Configuration of an Information Processing System]

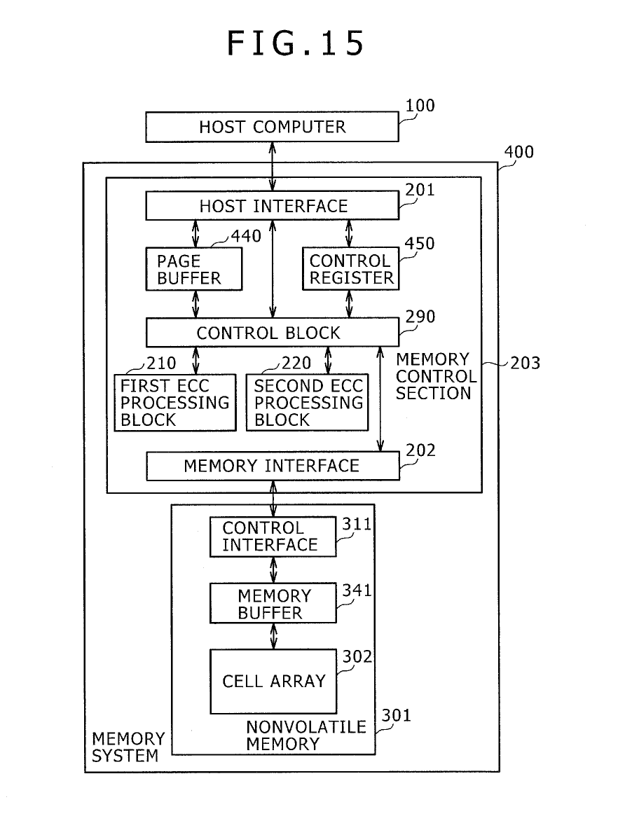

Referring to FIG. 15, there is shown an exemplary configuration of an information processing system in a third embodiment of the technology disclosed herein. The information processing system has a host computer 100, a nonvolatile memory 301, and a memory control section 203. The memory control section 203 and the nonvolatile memory 301 make up a memory system 400. The host computer 100 issues a request to the memory system 400 for reading or writing data.

In the third embodiment, the nonvolatile memory 301 assumes 34 bytes for a read access unit and a write access unit. The access unit includes data and an error correction code for example. The nonvolatile memory 301 also assumes 512 bytes as a data page size in the execution of page access. When requesting the nonvolatile memory 301 for reading of writing data, the host computer 100 specifies the mode of an error correction code. If the mode specification is a first mode (a 32-byte mode), an error correction code is attached to every 32 data bytes in the page. The error correction code is referred to as a first ECC. On the other hand, if the mode specification is a second mode (a 512-byte mode), then an error correction code is attached to all data of 512 bytes in the page. The error correction code is referred to as a second ECC.

The nonvolatile memory 301 retains data when the power thereof is off. The nonvolatile memory 301 is largely categorized into a flash memory compatible with data access in large sizes and a nonvolatile random access memory (NVRAM) that allows high-speed random access in small data units. A typical flash memory is a NAND-type flash memory. On the other hand, a typical NVRAM is PCRAM, MRAM, or ReRAM, for example.

The nonvolatile memory 301 has a cell array 302, a memory buffer 341, and a control interface 311. The cell array 302 has memory cells for storing the data values of bits, the memory cells arranged in a matrix. Each memory cell is nonvolatile, that is, retains data when the power is off. The memory buffer 341 holds data to be written to the cell array 302 or data read from the cell array 302. The control interface 311 provides interface with the memory control section 203.

The memory control section 203 controls the nonvolatile memory 301. The memory control section 203 has a first ECC processing block 210, a second ECC processing block 220, a page buffer 440, a control register 450, a control block 290, a host interface 201, and a memory interface 202.

The first ECC processing block 210 generates a first ECC or executes error correction based on the generated first ECC. The second ECC processing block 220 generates a second ECC or executes error correction on the basis of the generated second ECC.

The page buffer 440 holds data of 512 bytes in the page. To be more specific, the page buffer 440 holds on a page basis the write data specified by the host computer 100 or the read data read from the nonvolatile memory 301.

The control register 450 holds a control command issued by the host computer 100 or a status supplied from the nonvolatile memory 301.

The control block 290 controls the memory control section 203 in its entirety. The host interface 201 provides interface with the host computer 100. The memory interface 202 provides interface with the nonvolatile memory 301.

### [Functional Configuration of the Memory Control Section]

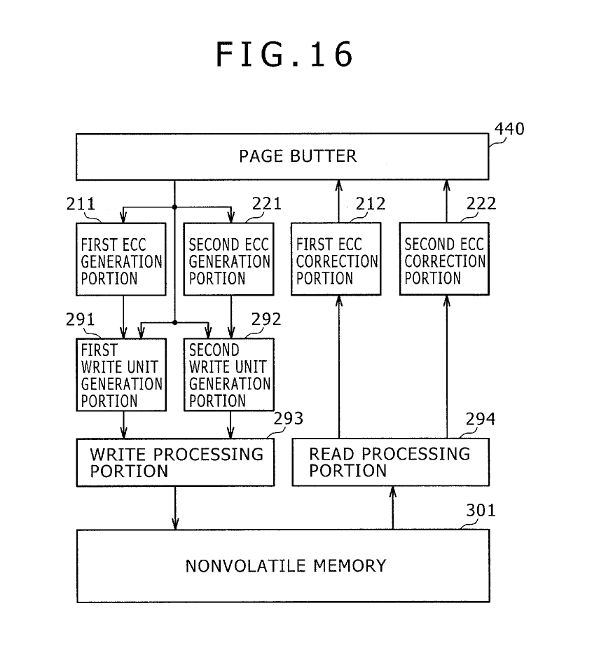

Referring to FIG. 16, there is shown an exemplary functionary configuration of the memory control section 203 in the third embodiment of the technology disclosed herein. The memory control section 203 has a first ECC generation portion 211, a first ECC correction portion 212, a second ECC generation portion 221, a second ECC correction portion 222, a first write unit generation portion 291, a second write unit generation portion 292, a write processing portion 293, and a read processing portion 294. The first ECC generation portion 211 and the first ECC correction portion 212 are functions of the first ECC processing block 210. The second ECC generation portion 221 and the second ECC correction portion 222 are functions of the second ECC processing block 220. The first write unit generation portion 291, the second write unit generation portion 292, the write processing portion 293, and the read processing portion 294 are functions of the access control block 290.

The first ECC generation portion 211 generates a first ECC from 32-byte data supplied from the page buffer 440. The second ECC generation portion 221 generates a second ECC from 512-byte data supplied from the page buffer 440.

The first write unit generation portion 291 pairs data obtained by dividing write data every 32 bytes with the first error correction code of this data and attaches mode information indicative of 32-byte mode to the pair, thereby generating the resultant data as a first write unit.

The second write unit generation portion 292 divides, into a predetermined size, a pair of data obtained by dividing write data every 512 bytes and a second error correction code for this data and attaches mode information indicative of 512-byte mode, thereby generating the resultant data as a second write unit.

The write processing portion 293 writes the first write unit or the second write unit to the nonvolatile memory 301. To be more specific, if a write command of 32-byte mode is issued, the write processing portion 293 writes data to the nonvolatile memory 301 with the first write unit as access unit. If a write command of 512-byte mode is issued, the write processing portion 293 writes data to the nonvolatile memory 301 with the second write unit as access unit.

The read processing portion 294 reads data from the nonvolatile memory 301 for each access unit. The read processing portion 294 extracts mode information from an access unit to determine whether this access unit has been written in the 32-byte mode or the 512-byte mode.

If the mode information is found to be indicative of the 32-byte mode, then the first ECC correction portion 212 execute error correction from the 32-byte data included in the access unit and the first error correction code of the 32-byte data. If the mode information is found to be indicative of the 512-byte mode, then the second ECC correction portion 222 executes error correction from the data divided every 512 bytes included in the access unit and the second error correction code of this data.

### [Format Configuration of Access Units]

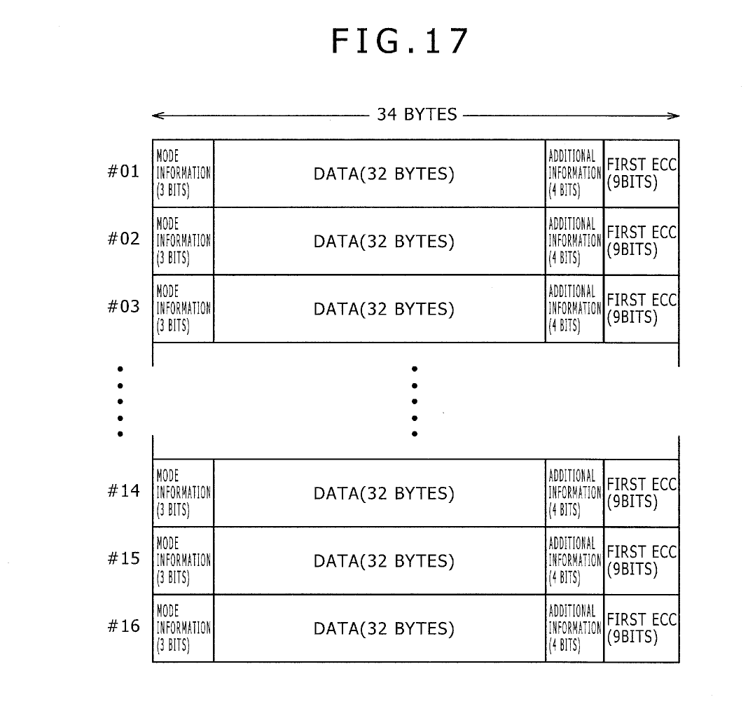

Referring to FIG. 17, there is shown an exemplary format configuration of a first write unit in the third embodiment of the technology disclosed herein. Each first write unit has 3-bit mode information, 32-byte data, 4-bit additional information, and a 9-bit first ECC from the beginning of the format.

The mode information is indicative whether this access unit is the first write unit or the second write unit. In this example, the access unit is the first write unit. The mode information is not the target of the first ECC but reinforces the data retainability by providing a redundant bit as will be described later.

The data is 32 bytes long throughout the first write units. Therefore, in order to write 512-byte page data, 16 first write units are required. The additional information is about the 32-byte data and is used as required.

The first ECC is a first error correction code generated for the data and the additional information. Therefore, the generation of a first ECC and error detection and correction processing based on the generated first ECC are executed in each write unit independently.

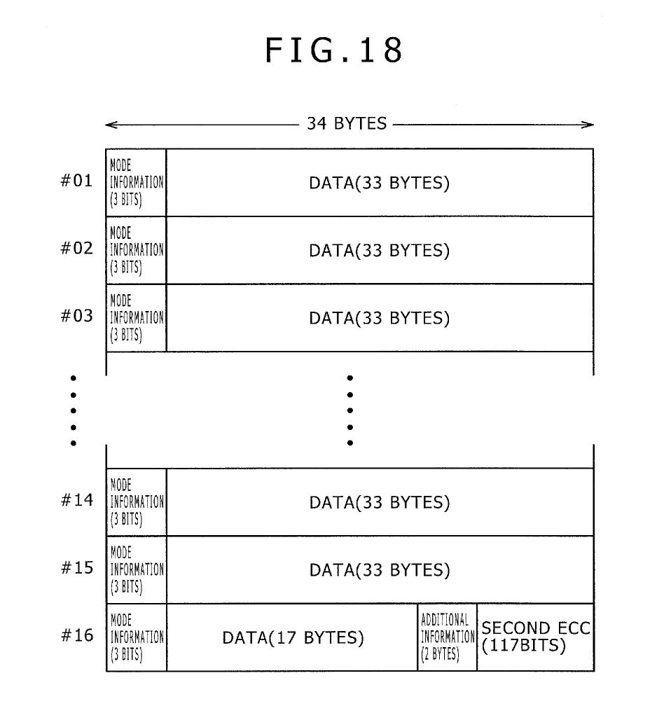

Referring to FIG. 18, there is shown an exemplary format configuration of a second write unit in the third embodiment of the technology disclosed herein. The second write units have no equal format; namely, a total of 16 second write units have 512-byte data, 2-byte additional information, and 117-bit second ECC. At the beginning of each second write unit, 3-bit mode information is attached.

The mode information is indicative whether this access unit is a first write unit or a second write unit. In this example, this access unit is a second write unit. The mode information is not the target of the second ECC but reinforces the data retainability by providing a redundant bit as will be described later.

The second ECC is a second error correction code generated for the data and the additional information. Therefore, in a state of a total of 16 second write units, the generation of the second ECC and the error detection and correction processing are executed.

### [Comparison Between the First ECC and the Second ECC]

Now, the first ECC and the second ECC are compared with each other in bit error rate. If it is assumed that bit error rate f before ECC application be independent and identically distributed, then uncorrectable bit error UBE after ECC application is obtained from the following equation (1) where c bits among n bits are correctable. It should be noted that n is representative of the number of concurrently read bits.

$$UBE = {\sum }_{x = c + 1}^{n} \frac{x}{n} \cdot ( \begin{matrix}n \\ x\end{matrix} ) \cdot {f}^{x} \cdot {( 1 - f )}^{( n - x )} \qquad ( 1 )$$

First, in order to execute 1-bit detection and correction processing on 32-byte data, a 9-bit error correction code is required. In equation (1) above, if the bit error rate of 32 bytes is 10⁻⁶, then the bit error rate after the 1-bit correction is about 10⁻⁹. In order to execute 2-bit detection and correction processing on 32-byte data, an 18-bit error correction code is required. In equation (1) above, if the bit error rate of 32 bytes is 10⁻⁶, then the bit error rate after the 2-bit correction is about 10⁻¹³.

On the other hand, in order to execute 3-bit detection and correction processing on 512-byte data, a 39-bit error correction code is required. In equation (1) above, if the bit error rate of 512 bytes is 10⁻⁶, then the bit error rate after the 3-bit correction is about 10⁻¹⁴. This is equal to the bit error rate obtained when 2-bit detection and correction processing is assumed for 32-byte data.

In order to execute 8-bit detection and correction processing on 512-byte data, a 104-bit error correction code is required. In equation (1) above, if the bit error rate of 512 bytes is 10⁻⁶, then the bit error rate after the 8-bit correction processing is about 10⁻²⁰. This still lowers the bit error rate. The size ratio of error correction code in this case is smaller than that obtained when 1-bit detection and correction processing is executed on 32-byte data.

In the present embodiment, a 1-bit first ECC is attached to the data and additional information totaling about a little less than 34 bytes and a 117-bit second ECC is attached to the data and additional information totaling about 514 bytes. Therefore, the bit error rate by the second ECC is small enough as compared with the bit error rate by the first ECC and the size ratio of the second ECC is small enough as compared with the size ratio of the first ECC.

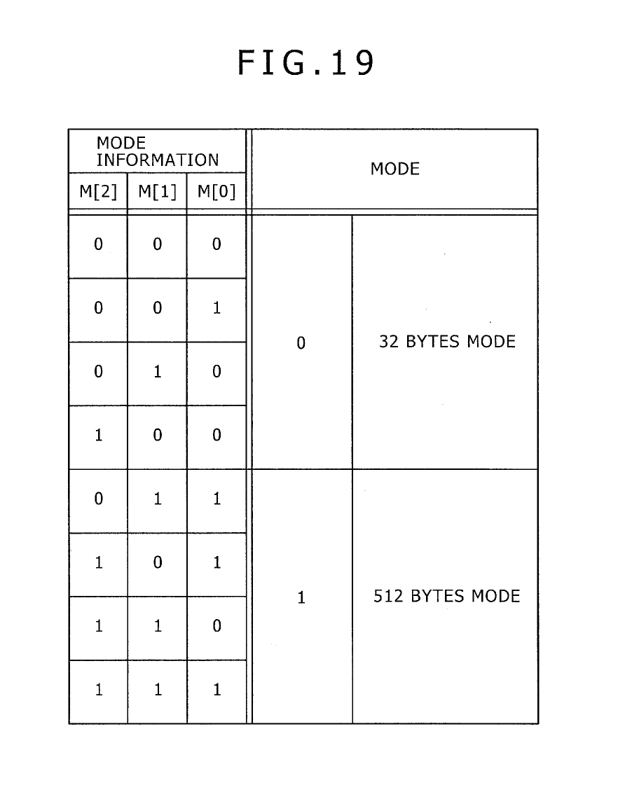

Referring to FIG. 19, there is shown an exemplary format configuration of the mode information in the third embodiment of the technology disclosed herein. As described above, the mode information is made up of three bits, so that this format configuration is to have the same number of bits under normal circumstances. Namely, “0” is indicative of the 32-byte mode and “1” is indicative of the 512-byte mode. However, there is a chance for any bit to be erroneously inverted, so that two more bits are provided for redundancy. Hence, the mode is determined on the basis of a result of majority decision executed in the three bits. Consequently, even if a 1-bit error occurs, the mode can be determined correctly. Namely, it may be understood that, of the three bits making up the mode information, any one bit is attached with the other two bits as an error correction code.

The mode information occupies the start three bits of the access unit and exists at a location common to the first write unit and the second write unit. Therefore, only checking the start three bits of the access unit can determine whether the mode information is indicative of the 32-byte mode or the 512-byte mode. It should be noted that the mode information is indicated by the first three bits of the access unit in this example; however, the mode information may be arranged at any one of other location that is common to the first write unit and the second write unit.

### [Read Processing Procedure in the 32-Byte Mode]

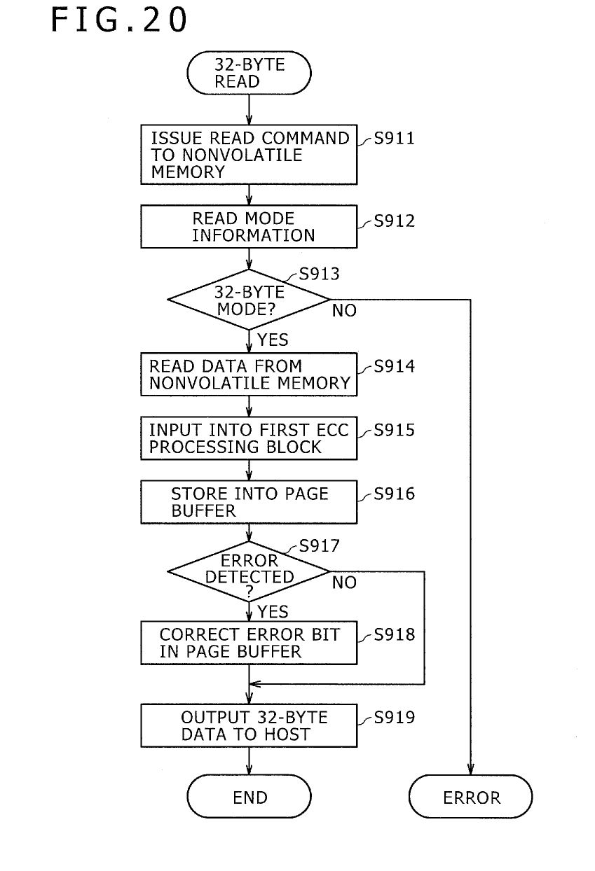

Referring to FIG. 20, there is shown a flowchart indicative of an exemplary read processing procedure in the 32 bytes in the third embodiment of the technology disclosed herein. When a read command is issued to the nonvolatile memory 301 (step S911), mode information located at the beginning of the access unit is read from the nonvolatile memory 301 by the read processing portion 294 (step S912). At this moment, if the mode information is not indicative of the 32-byte mode (step S913: No), then this procedure comes to an end with error due to mode mismatching.

If the mode information is indicative of the 32-byte mode (step S913: Yes), the data, additional information, and first ECC subsequent to the mode information are read by the read processing portion 294 (step S914). Next, the data and the additional information are entered in the first ECC correction portion 212 of the first ECC processing block 210 (step S915). Consequently, the error detection processing based on the first ECC is executed. Then, the data is stored in the page buffer 440 (step S916). At this moment, if an error is detected (step S917: Yes), the error correction processing is executed on the failing bit in the page buffer 440 (step S918). Then, the 32-byte data is outputted from the page buffer 440 to the host computer 100 (step S919).

### [Read Processing Procedure in the 512-Byte Mode]

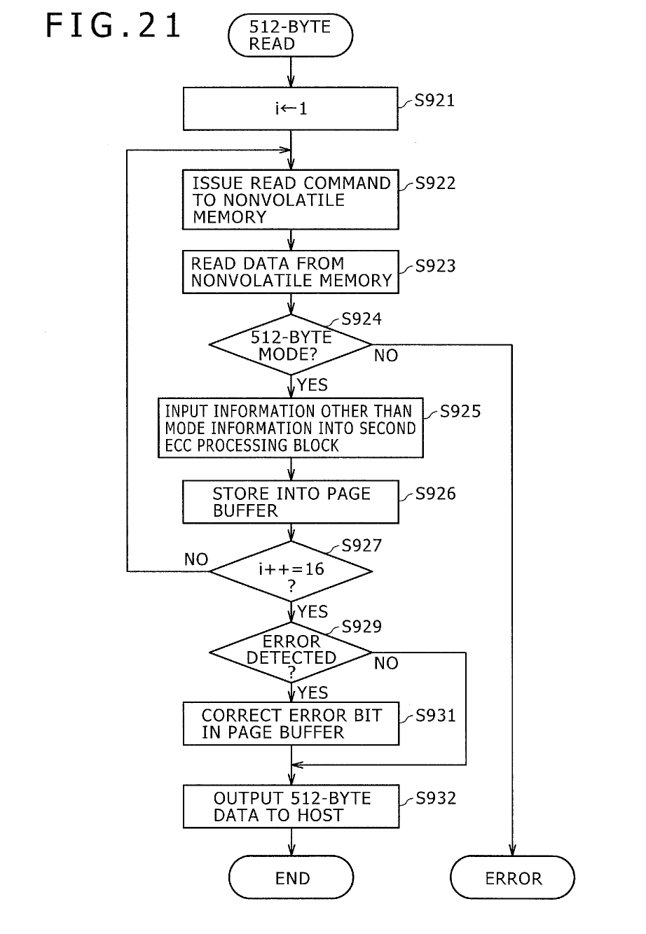

Referring to FIG. 21, there is shown a flowchart indicative of an exemplary read processing procedure in the 512-byte mode in the third embodiment of the technology disclosed herein. Here, control variable i for sequentially accessing 16 access units is assumed and “1” is substituted as the initial value of this control variable i (step S291).

When a read command is issued to the nonvolatile memory 301 (step S922), the access units are read from the nonvolatile memory 301 by the read processing portion 294 (step S923). At this moment, if the mode information is not indicative of the 512-byte mode (step S924: No), then this procedure comes to an end with error due to mode mismatching.

If the mode information is indicative of 512 bytes (step S924: Yes), then the information other than the mode information is entered in the second ECC correction portion 222 of the second ECC processing block 220 (step S925). Consequently, the error detection processing based on the second ECC is sequentially executed. Subsequently, the data is stored in the page buffer 440 (step S926).

Control variable i increments by one. The processing of step S922 and subsequent steps is repeated until control variable i reaches 16 (step S927: No). Consequently, the error detection processing is sequentially executed as described above. Then, when control variable i is 16 (step S927: Yes), the above-mentioned repetition is terminated (step S927: Yes) with the data and additional information included in the 16th access unit being the last input in the second ECC correction portion 222 (step S925). Consequently, a result of the error detection based on the second ECC is obtained. At this moment, if an error has been detected (step S929: Yes), the error correction processing is executed on the failing bit in the page buffer 440 (step S931). Subsequently, the 512-byte data in the page buffer 440 is outputted to the host computer 100 (steep S932).

In the third embodiment, the data read from the nonvolatile memory 301 can be entered in the second ECC correction portion 222 as required to be error-corrected by the second ECC read last, so that the data halfway in the processing need not be temporarily held. If the data and the second ECC are dispersed in other than the last access unit, for example, it is required to extract these data and second ECC from the access unit and hold the extracted data and second ECC. In this respect, the third embodiment need not temporarily hold the data halfway in the processing, thereby saving the storage area.

### [Write Processing Procedure in the 32-Byte Mode]

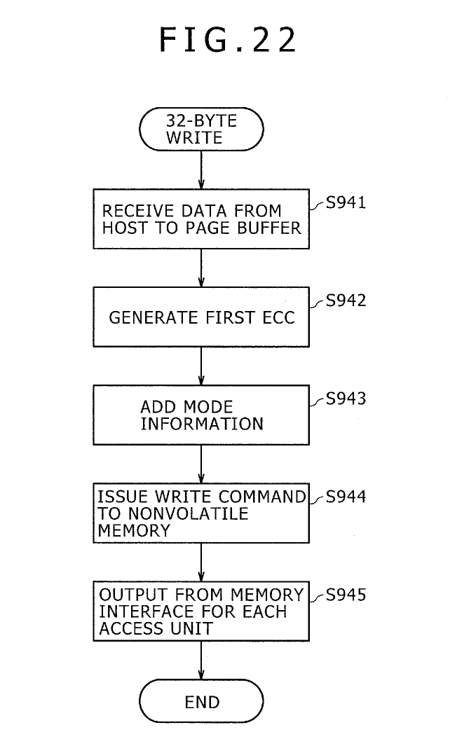

Referring to FIG. 22, there is shown a flowchart indicative of an exemplary write processing procedure in the 32-byte mote in the present embodiment of the technology disclosed herein. When write data is received along with a write command from the host computer 100, the received write data and additional information are stored in the page buffer 440 (step S941). Then, the first ECC is generated by the first ECC generation portion 211 for the 32-byte data and additional information in the page buffer 440 (step S942).

Next, as described above with reference to FIG. 17, the mode information indicative of the 32-byte mode is attached to the beginning and the first write unit followed by the data, the additional information, and the first ECC is generated by the first write unit generation portion 291 (step S943).

The write processing portion 293 issues a write command to the nonvolatile memory 301 (step S944). Then, with the generated first write unit being the access unit, the output to the nonvolatile memory 301 is executed in every access unit from the memory interface 202 (step S945).

### [Write Processing Procedure in the 512-Byte Mode]

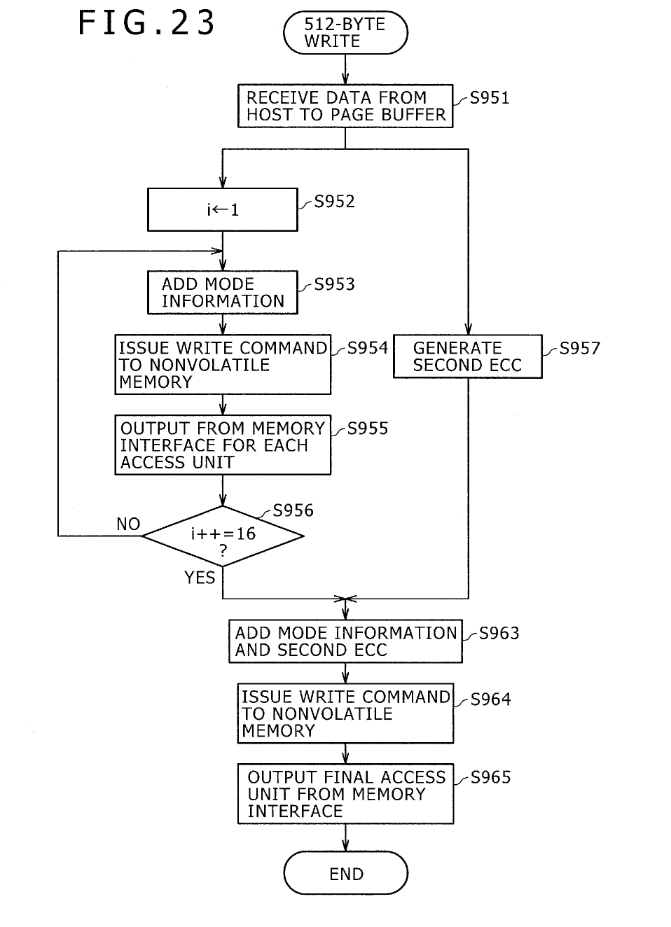

Referring to FIG. 23, there is shown a flowchart indicative of an exemplary write processing procedure in the 512-byte mode in the third embodiment of the technology disclosed herein. When write data is received along with a write command from the host computer 100, the received write data and additional information are stored in the page buffer 440 (step S951). Consequently, the second ECC is generated by the second ECC generation portion 221 for the 512-byte data and additional information in the page buffer 440 concurrently with the output for every subsequent access unit (step S957).

On the other hand, control variable i for sequentially accessing 16 access units is assumed and “1” is substituted as the initial value of this control variable i (step S952). Next, as described above with reference to FIG. 18, the mode information indicative of the 512-byte mode is attached to the beginning and the second write units (#01 through #15) followed by the data are generated by the second write unit generation portion 292 (step S953).

The write processing portion 293 issues a write command to the nonvolatile memory 301 (step S954). Then, with the generated second write units being the access units, output to the nonvolatile memory 301 is executed from the memory interface 202 for each access unit (step S955).

Control variable i is incremented by one and the processing of step S953 and subsequent steps is repeated until 16 is reached (step S956: No). When control variable i has reached 16 (step S956: Yes), the mode information indicative of the 512-byte mode is attached to the beginning in the 16th second write unit as described above with reference to FIG. 18, and the second write unit followed by the data, the additional information, and the second ECC is generated by the second write unit generation portion 292 (sep S963).

The write processing portion 293 issues a write command to the nonvolatile memory 301 (step S964). Next, with the generated second write units being the access units, output to the nonvolatile memory 301 is executed from the memory interface 202 for every access unit (step S965).

In the third embodiment, write data is entered in the second ECC generation portion 221 as required and the second ECCs collectively written in the last second write unit, so that there occurs no wait in the writing of the other second write units. If the data and the second ECC are dispersed in the second write units other than the last second write unit, for example, a wait for the second ECC to be generated last occurs in writing the second write unit, so that the processing time of the whole write processing is delayed. In this respect, according to the third embodiment, no wait occurs in writing the second write unit, thereby enhancing the speed of the whole write processing.

As described above and according to the third embodiment, the novel arrangement of the data and the second ECC in the 512-byte mode saves the storage area necessary for read processing and, at the same time, enhances the speed of the execution of write processing. In addition, the arrangement of mode information at a predetermined location of access unit allows the quick determination of the mode; the 32-byte mode or the 512-byte mode.

### 5. Variations

In the third embodiment described above, it is assumed that mode information be not the target of the first ECC or the second ECC; instead of mode information, 3-bit configuration including a redundant bit is employed. Alternatively, it is also practicable to employ a configuration in which mode information is targeted by the first ECC or the second ECC. To be more specific, in step 942, the first ECC is generated along with mode information and, in step S957, the second ECC along with mode information. In this case, the error detection based on the first ECC with the mode information is executed in step S915 and the error correction based on the first ECC with the mode information is executed in step S917. Further, the error detection based on the second ECC with the mode information is executed in step S928 and the error correction based on the second ECC with the mode information is executed in step S931.

It should be noted that the embodiments described above are illustrative only for realizing the technology disclosed herein. The matters in the embodiments are respectively correlated with the matters specifying the disclosure in the scope of claims herein. Likewise, the matters specifying the disclosure in the scope of claims herein are respectively correlated with the matters in the embodiments of the technology disclosed herein having the same names. However, the technology disclosed herein is not limited to the embodiments and it is to be understood that changes and variations may be made without departing from the spirit or scope of the claims herein.

The sequence of processing procedures described in the embodiments mentioned above may be understood as a method having these sequence of procedures or a computer program for making a computer execute the sequence of procedures or a recording media storing such a computer program. For the recording media, a memory card based on a nonvolatile memory or an SSD (Solid State Drive) based on a nonvolatile memory is available.

It should be noted that the technology disclosed herein may take the following configuration.

(1) A storage control apparatus including:

an error correction code attachment rule hold block configured to hold attachment rules of attaching error correction codes to a group of data sequences stored in memory by relating the attachment rules to the group of data sequences for each address of the group of data sequences; and

an error correction portion configured, if an access occurs to the memory, to execute error correction on the group of data sequences stored in the memory in accordance with the attachment rules related with an access address at which the access occurred.

(2) The storage control apparatus described in paragraph (1) above, wherein

the attachment rules define one of the cases in which the error correction codes are generated from a whole of the group of data sequences and the error correction codes are generated independently of each of a plurality of partial data sequences configuring the group of data sequences.

(3) The storage control apparatus described in paragraph (1) or (2) above, wherein,

if the attachment rules related with the access address are found defining that the error correction codes are generated independently of each of a plurality of partial data sequences configuring the group of data sequences, the error correction portion executes error correction only on a partial data sequence related with the access among the plurality of partial data sequences.

(4) The storage control apparatus described in any of paragraphs (1) to (3) above, further including:

an error correction code generation portion configured, if a write access to the memory occurs, to generate an error correction code for write data associated with the write access in accordance with the attachment rules specified in the write access.

(5) The storage control apparatus described in paragraph (4) above, wherein,

if the attachment rules related with the write address are found defining that the error correction code is generated independently of each of a plurality of partial data sequences configuring the group of data sequences, the error correction code generation portion generates an error correction code only for a partial data sequence associated with the write access among the plurality of partial data sequences.

(6) The storage control apparatus described in any of paragraphs (1) to (5) above, wherein

the error correction code attachment rule hold block holds the attachment rules as instructed by a host computer that issues a request.

(7) The storage control apparatus described in any of paragraphs (1) to (6) above, wherein

if a write access to the memory occurs, the error correction code attachment rule hold block holds the attachment rules specified in the write access by relating the attachment rules with a write address associated with the write access.

(8) The storage control apparatus described in any of paragraphs (1) to (7) above, further including:

an address translation block configured, if an access address to the memory is a logical address, to translate the logical address to a physical address and output the physical address to the memory,

wherein

the error correction code attachment rule hold block holds the attachment rules by relating the attachment rules with the logical address of each of the group of data sequences, and

the error correction portion execute error correction on the group of data sequences stored in the memory in accordance with the attachment rules related with the logical address.

(9) The storage control apparatus described in any of paragraphs (1) to (8) above, further including:

an address translation block configured, if an access address to the memory is a logical address, to translate the logical address to a physical address and output the physical address to the memory,

wherein

the error correction code attachment rule hold block holds the attachment rules by relating the physical address of each of the group of data sequences, and

the error correction portion executes error correction on the plurality of data sequences stored, in the memory in accordance with the attachment rules related with the physical address.

(10) A storage apparatus including:

a memory configured to store error correction codes for a group of data sequences along with this group of data sequences in a data area;

an error correction code attachment rule hold block configured to hold error correction code attachment rules for the above-mentioned group of data sequences by relating the rules with each address of the above-mentioned data sequence; and

an error correction portion configured, if an access to the above-mentioned memory occurs, to execute error correction on the above-mentioned group of data sequences stored in the memory by following the above-mentioned attachment rules related with each access address.

(11) The storage apparatus described in paragraph (10) above, wherein

the above-mentioned attachment rules define whether the above-mentioned error correction codes are generated from entirety of the above-mentioned group of data sequences or these error correction codes are generated independently of each of a plurality of partial data sequences making up the above-mentioned group of data sequences, and

if the attachment rules define that these error correction codes are generated independently of each of a plurality of partial data sequences making up the above-mentioned group of data sequences, then the above-mentioned memory stores these error correction codes at locations continuous to each of the plurality of partial data sequences.

(12) The storage apparatus described in paragraph (10) or (11) above, wherein the memory is a nonvolatile memory.

(13) An information processing system including:

a memory that stores error correction codes for a group of data sequences;

an error correction code attachment rule hold block configured to hold attachment rules of attaching error correction codes to a group of data sequences stored in memory by relating said attachment rules to said group of data sequences for each address of said group of data sequences;

an error correction portion configured, if an access occurs to said memory, to execute error correction on said group of data sequences stored in said memory in accordance with said attachment rules related with an access address at which said access occurred; and

a host computer configured to issue a request to the memory for reading or writing of the data area.

(14) A storage control method including:

defining attachment rules of error correction codes for a group of data sequences stored in a memory by relating these attachment rules with each address of the group of data sequences; and

executing error correction on the group of data sequences stored in the memory in accordance with the attachment rules related with each access address if an access to the memory occurs.

(15) A storage control apparatus including:

a first write unit generation portion configured, if a write command of a first mode is issued to a memory, to generate, as a first write unit, write data by pairing data obtained by delimiting, by a first size smaller than an access unit of the memory, write data associated with the write command of the first mode with a first error correction code for the data and attaching mode information indicative of the first mode to each pair;

a second write unit generation portion configured, if a write command of a second mode is issued to the memory, to generate, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair; and

a write processing portion configured, if the write command of the first mode is issued to same memory, to write the first write unit to the memory as an access unit and, if the write command of the second mode is issued to the memory, to write the second write unit to the memory as the access unit.

(16) The storage control apparatus described in paragraph (15) above, further including:

a read processing portion configured to read the access unit from the memory to extract the mode information;

a first error correction processing portion configured, if the mode information is indicative of the first mode, to execute error correction on the basis of the data of the first size included in the access unit and the first error correction code; and

a second error correction processing portion configured, if the mode information is indicative of the second mode, to execute error correction on the basis of the data delimited by the predetermined size included in the access unit and the second error correction code.

(17) The storage control apparatus described in paragraph (15) or (16) above, further including:

a first error correction code generation portion configured to generate a first error correction code for the data of the first size; and

a second error correction code generation portion configured to generate a second error correction code for the data of the second size.

(18) The storage control apparatus described in any of paragraphs (15) to (17) above, wherein

the mode information is stored at a predetermined location of the access unit.

(19) The storage control apparatus described in paragraph (18) above, wherein

the mode information is stored at the beginning of the access unit.

(20) The storage control apparatus described in any of paragraphs (15) to (18) above, wherein

the first write unit generation portion and the second write unit generation portion attach a third error correction code of the mode information to the mode information.

(21) The storage control apparatus described in paragraph (20) above, wherein

the third error correction code is an error correction code for executing error correction by a bit majority rule.

(22) The storage control apparatus described in paragraph (20) above, wherein

the read processing portion executes error correction on the mode information on the basis of the mode information and the third error correction code.

(23) A storage apparatus including:

a memory that is accessed by a predetermined access unit;

a first write unit generation portion configured, if a write command of a first mode is issued to the memory, to generate, as a first write unit, write data by pairing data obtained by delimiting, by a first size smaller than an access unit of the memory, write data associated with the write command of the first mode with a first error correction code for the data and attaching mode information indicative of the first mode to each pair;

a second write unit generation portion configured, if a write command of a second mode is issued to the memory, to generate, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair; and

a write processing portion configured, if the write command of the first mode is issued to same memory, to write the first write unit to the memory as an access unit and, if the write command of the second mode is issued to the memory, to write the second write unit to the memory as the access unit.

(24) The storage apparatus described in paragraph (23) above, wherein the memory is a nonvolatile memory.

(25) An information processing system including:

a memory that is accessed by a predetermined access unit;

a first write unit generation portion configured, if a write command of a first mode is issued to the memory, to generate, as a first write unit, write data by pairing data obtained by delimiting, by a first size smaller than an access unit of the memory, write data associated with the write command of the first mode with a first error correction code for the data and attaching mode information indicative of the first mode to each pair;

a second write unit generation portion configured, if a write command of a second mode is issued to the memory, to generate, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair;

a write processing portion configured, if the write command of the first mode is issued to same memory, to write the first write unit to the memory as an access unit and, if the write command of the second mode is issued to the memory, to write the second write unit to the memory as the access unit; and

a computer that issues a write command and a read command to the above-mentioned memory.

(26) A storage control method including the steps of:

if a write command of a first mode is issued to a memory, generating, as a first write unit, write data by pairing data obtained by delimiting, by a first size smaller than an access unit of the memory, write data associated with the write command of the first mode with a first error correction code for the data and attaching mode information indicative of the first mode to each pair;

if a write command of a second mode is issued to the memory, to generating, as a second write unit, write data by delimiting, by a predetermined size, a pair of data obtained by delimiting write data associated with the write command of the second mode by a second size larger than the access unit of the memory and a second error correction code for the data and attaching the mode information indicative of the second mode to each delimited pair; and,

if the write command of the first mode is issued to same memory, writing the first write unit to the memory as an access unit and, if the write command of the second mode is issued to the memory, writing the second write unit to the memory as the access unit.

The present technology contains subject matter related to those disclosed in Japanese Priority Patent Applications JP 2011-244266 and JP 2012-004578 filed in the Japan Patent Office on Nov. 8, 2011, and Jan. 13, 2012, respectively, the entire contents of which are hereby incorporated by reference.

What is claimed is:

1. A storage control apparatus comprising:
an error correction code attachment rule hold block configured to hold attachment rules of attaching error correction codes to a group of data sequences stored in memory by relating said attachment rules to said group of data sequences for each address of said group of data sequences; and
an error correction portion configured, if an access occurs to said memory, to execute error correction on said group of data sequences stored in said memory in accordance with said attachment rules related with an access address at which said access occurred.

2. The storage control apparatus according to claim 1, wherein
said attachment rules define one of the cases in which said error correction codes are generated from a whole of said group of data sequences and said error correction codes are generated independently of each of a plurality of partial data sequences configuring said group of data sequences.

3. The storage control apparatus according to claim 1, wherein,
if said attachment rules related with said access address are found defining that said error correction codes are generated independently of each of a plurality of partial data sequences configuring said group of data sequences, said error correction portion executes error correction only on a partial data sequence related with said access among said plurality of partial data sequences.

4. The storage control apparatus according to claim 1, further comprising:
an error correction code generation portion configured, if a write access to said memory occurs, to generate an error correction code for write data associated with said write access in accordance with said attachment rules specified in said write access.

5. The storage control apparatus according to claim 4, wherein,
if said attachment rules related with said write address are found defining that said error correction code is generated independently of each of a plurality of partial data sequences configuring said group of data sequences, said error correction code generation portion generates an error correction code only for a partial data sequence associated with said write access among said plurality of partial data sequences.

6. The storage control apparatus according to claim 1, wherein
said error correction code attachment rule hold block holds said attachment rules as instructed by a host computer that issues a request.

7. The storage control apparatus according to claim 1, wherein
if a write access to said memory occurs, said error correction code attachment rule hold block holds said attachment rules specified in said write access by relating said attachment rules with a write address associated with said write access.

8. The storage control apparatus according to claim 1, further comprising:
an address translation block configured, if an access address to said memory is a logical address, to translate said logical address to a physical address and output said physical address to said memory,
wherein
said error correction code attachment rule hold block holds said attachment rules by relating said attachment rules with said logical address of each of said group of data sequences, and
said error correction portion execute error correction on said group of data sequences stored in said memory in accordance with said attachment rules related with said logical address.

9. The storage control apparatus according to claim 1, further comprising:
an address translation block configured, if an access address to said memory is a logical address, to translate said logical address to a physical address and output said physical address to said memory,
wherein
said error correction code attachment rule hold block holds said attachment rules by relating said physical address of each of said group of data sequences, and
said error correction portion executes error correction on said plurality of data sequences stored in said memory in accordance with said attachment rules related with said physical address.

10. A storage control apparatus comprising:
a first write unit generation portion configured, if a write command of a first mode is issued to a memory, to generate, as a first write unit, write data by pairing data obtained by delimiting, by a first size smaller than an access unit of said memory, write data associated with said write command of said first mode with a first error correction code for said data and attaching mode information indicative of said first mode to each pair;
a second write unit generation portion configured, if a write command of a second mode is issued to said memory, to generate, as a second write unit, write data by delimiting, by a predetermined size, a pair of data obtained by delimiting write data associated with said write command of said second mode by a second size larger than said access unit of said memory and a second error correction code for said data and attaching said mode information indicative of said second mode to each delimited pair; and
a write processing portion configured, if said write command of said first mode is issued to same memory, to write said first write unit to said memory as an access unit and, if said write command of said second mode is issued to said memory, to write said second write unit to said memory as said access unit.

11. The storage control apparatus according to claim 10, further comprising:
a read processing portion configured to read said access unit from said memory to extract said mode information;
a first error correction processing portion configured, if said mode information is indicative of said first mode, to execute error correction on the basis of said data of said first size included in said access unit and said first error correction code; and
a second error correction processing portion configured, if said mode information is indicative of said second mode, to execute error correction on the basis of said data delimited by said predetermined size included in said access unit and said second error correction code.

12. The storage control apparatus according to claim 10, further comprising:
a first error correction code generation portion configured to generate a first error correction code for said data of said first size; and
a second error correction code generation portion configured to generate a second error correction code for said data of said second size.

13. The storage control apparatus according to claim 10, wherein
said mode information is stored at a predetermined location of said access unit.

14. The storage control apparatus according to claim 13, wherein
said mode information is stored at the beginning of said access unit.

15. The storage control apparatus according to claim 10, wherein
said first write unit generation portion and said second write unit generation portion attach a third error correction code of said mode information to said mode information.

16. The storage control apparatus according to claim 15, wherein
said third error correction code is an error correction code for executing error correction by a bit majority rule.

17. The storage control apparatus according to claim 15, wherein
said read processing portion executes error correction on said mode information on the basis of said mode information and said third error correction code.
